(19) United States
(12) Patent Application Publication
(10) Pub. No.: US 2026/0082664 A1
(43) Pub. Date: Mar. 19, 2026

(54) SEMICONDUCTOR DEVICE WITH ELECTRODE HAVING STEP-SHAPED SIDEWALL AND METHOD OF PREPARING THE SAME

(71) Applicant: NANYA TECHNOLOGY CORPORATION, NEW TAIPEI CITY (TW)

(72) Inventor: CHIN-LING HUANG, NEW TAIPEI CITY (TW)

(21) Appl. No.: 18/917,554

(22) Filed: Oct. 16, 2024

Related U.S. Application Data
(62) Division of application No. 18/890,290, filed on Sep. 19, 2024.

(51) Int. Cl. H01L 29/423; H01L 21/3105; H01L 21/3213; H01L 21/764

(52) U.S. Cl. CPC H10D 64/518; H10P 50/267; H10P 95/062; H10W 10/021; H10W 10/20

(57) ABSTRACT

A semiconductor device includes a bottom electrode structure disposed over a semiconductor substrate. The bottom electrode structure includes a first metal layer, a second metal layer, a third metal layer, a fourth metal layer, and a fifth metal layer, arranged from bottom to top. The first metal layer, the third metal layer and the fifth metal layer include a first metal material, and the second metal layer and the fourth metal layer include a second metal material different from the first metal material. The semiconductor device also includes a high-k dielectric structure disposed on opposite sidewalls of the bottom electrode structure. The opposite sidewalls of the bottom electrode structure are step-shaped. The semiconductor device further includes a top electrode structure laterally surrounding the bottom electrode structure and separated from the bottom electrode structure by the high-k dielectric structure.

### CROSS-REFERENCE TO RELATED APPLICATION

This application is a divisional application of U.S. Non-Provisional Application No. Ser. No. 18/890,290 filed Sep. 19, 2024, which is incorporated herein by reference in its entirety.

### TECHNICAL FIELD

The present disclosure relates to a semiconductor device and a method of preparing the same, and more particularly, to a semiconductor device with an electrode having a step-shaped sidewall and a method of preparing the same.

### DISCUSSION OF THE BACKGROUND

Semiconductor devices are essential for many modern applications. With advancement of electronic technology, semiconductor devices are becoming smaller in size while providing greater functionality and including greater amounts of integrated circuitry. Due to the miniaturized scale of semiconductor devices, wafer level chip scale packaging (WLCSP) is widely used for its low cost and relatively simple processes. Furthermore, numerous manufacturing operations are implemented within such small semiconductor devices.

The manufacturing and integration of semiconductor devices involve many complicated steps and operations. An increase in complexity of manufacturing and integrating the semiconductor device may cause deficiencies. Accordingly, there is a continuous need to improve the manufacturing process of semiconductor devices so that the deficiencies can be addressed.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method of fabricating a semiconductor device comprising providing a substrate; forming a first dielectric layer over the substrate and a second dielectric layer over the first dielectric layer; forming a bottom electrode structure over the first dielectric layer; forming a high-k dielectric structure on opposite sidewalls of the bottom electrode structure; forming a top electrode structure laterally surrounding the bottom electrode structure and separated from the bottom electrode structure by the high-k dielectric structure; forming a plurality of conductive plugs in a third dielectric layer over the bottom electrode structure, the high-k dielectric structure, the top electrode structure, and the second dielectric layer; forming a plurality of air gap structures in the third dielectric layer; and forming a plurality of conductive pads over the third dielectric layer. The opposite sidewalls of the bottom electrode structure are step-shaped.

Another aspect of the present disclosure provides a method of fabricating a semiconductor device comprising providing a substrate in a pattern-dense region; forming a first dielectric layer over the substrate; forming a semiconductor structure over the first dielectric layer; forming a first conductive plug, a second conductive plug and a third conductive plug over the semiconductor structure, wherein the first conductive plug, the second conductive plug and the third conductive plug are spaced apart from each other; and forming a first air gap structure and a second air gap structure over the semiconductor structure, wherein the first air gap structure is disposed between the first conductive plug and the second conductive plug and the second air gap structure is disposed between the second conductive plug and the third conductive plug.

Another aspect of the present disclosure provides a semiconductor device comprising a substrate with a first dielectric layer disposed thereon; a bottom electrode structure disposed over the first dielectric layer; a high-k dielectric structure disposed on opposite sidewalls of the bottom electrode structure, wherein the opposite sidewalls of the bottom electrode structure are step-shaped; a top electrode structure laterally surrounding the bottom electrode structure and separated from the bottom electrode structure by the high-k dielectric structure; a first conductive plug disposed over the top electrode structure, a second conductive plug disposed over the bottom electrode structure, and a third conductive plug disposed over the top electrode structure, wherein the first conductive plug, the second conductive plug and the third conductive plug are spaced apart from each other; and a first air gap structure and a second air gap structure disposed over the bottom electrode structure, the high-k dielectric structure and the top electrode structure. The bottom electrode structure comprises a first metal layer, a second metal layer disposed over the first metal layer, a third metal layer disposed over the second metal layer, a fourth metal layer disposed over the third metal layer, a fifth metal layer disposed over the fourth metal layer, a sixth metal layer disposed over the fifth metal layer, and a seventh metal layer disposed over the sixth metal layer. The first metal layer, the third metal layer, the fifth metal layer and the seventh metal layer comprise a first metal material. The second metal layer, the fourth metal layer and the sixth metal layer comprise a second metal material different from the first metal material. The first air gap structure is disposed between the first conductive plug and the second conductive plug. The second air gap structure is disposed between the second conductive plug and the third conductive plug.

Embodiments of a semiconductor device with an electrode having a step-shaped sidewall and method of preparing the same are provided in the disclosure. In some embodiments, the semiconductor device includes a bottom electrode structure, a high-k dielectric structure disposed on opposite sidewalls of the bottom electrode structure, and a top electrode structure laterally surrounding the bottom electrode structure and separated from the bottom electrode structure by the high-k dielectric structure. In some embodiments, the opposite sidewalls of the bottom electrode structure are step-shaped. Therefore, since the sidewalls of the bottom electrode structure comprise step-shaped sidewalls, a capacitor formed by the bottom electrode structure, the high-k dielectric structure, and the top electrode structure can exhibit an effective area greater than those in the prior art having a same footprint area, and a capacitance per unit area can be increased. As a result, a performance of the semiconductor device is improved.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device in accordance with some embodiments of the present disclosure.

FIG. 2 is a top view of a portion of a semiconductor device in accordance with some embodiments of the present disclosure. The cross-sectional view of FIG. 1 is taken along a sectional line A-A′ in FIG. 2.

FIG. 3 is a flow diagram of a method of preparing a semiconductor device in accordance with some embodiments of the present disclosure.

FIG. 4 is a cross-sectional view of an intermediate stage of sequentially forming a first dielectric layer and a second dielectric layer over a semiconductor substrate during the formation of the semiconductor device in accordance with some embodiments of the present disclosure.

FIG. 5 is a cross-sectional view of an intermediate stage of etching the second dielectric layer to form an opening exposing the first dielectric layer during the formation of the semiconductor device in accordance with some embodiments of the present disclosure.

FIG. 6 is a cross-sectional view of an intermediate stage of forming a plurality of metal layers (e.g., a first metal layer, a second metal layer, a third metal layer, a fourth metal layer, a fifth metal layer, a sixth metal layer, and a seventh metal layer, from bottom to top) in the opening during the formation of the semiconductor device in accordance with some embodiments of the present disclosure.

FIG. 7 is a cross-sectional view of an intermediate stage of forming a patterned photoresist over the metal layers during the formation of the semiconductor device in accordance with some embodiments of the present disclosure.

FIG. 8 is a cross-sectional view of an intermediate stage of performing a dry etching process using the patterned photoresist of FIG. 7 as a mask during the formation of the semiconductor device in accordance with some embodiments of the present disclosure.

FIG. 9 is a cross-sectional view of an intermediate stage of performing a wet etching process during the formation of the semiconductor device in accordance with some embodiments of the present disclosure.

FIG. 10 is a cross-sectional view of an intermediate stage of forming a patterned photoresist over the metal layers during the formation of the semiconductor device in accordance with some embodiments of the present disclosure.

FIG. 11 is a cross-sectional view of an intermediate stage of performing a dry etching process using the patterned photoresist of FIG. 10 as a mask during the formation of the semiconductor device in accordance with some embodiments of the present disclosure.

FIG. 12 is a cross-sectional view of an intermediate stage of performing a wet etching process during the formation of the semiconductor device in accordance with some embodiments of the present disclosure.

FIG. 13 is a cross-sectional of an intermediate stage of forming a patterned photoresist over the metal layers during the formation of the semiconductor device in accordance with some embodiments of the present disclosure.

FIG. 14 is a cross-sectional view of an intermediate stage of performing a dry etching process using the patterned photoresist of FIG. 13 as a mask during the formation of the semiconductor device in accordance with some embodiments of the present disclosure.

FIG. 15 is a cross-sectional view of an intermediate stage of performing a wet etching process during the formation of the semiconductor device in accordance with some embodiments of the present disclosure.

FIG. 16 is a cross-sectional view of an intermediate stage of forming a patterned photoresist over the metal layers during the formation of the semiconductor device in accordance with some embodiments of the present disclosure.

FIG. 17 is a cross-sectional view of an intermediate stage of performing a dry etching process using the patterned photoresist of FIG. 16 as a mask to form a bottom electrode structure during the formation of the semiconductor device in accordance with some embodiments of the present disclosure.

FIG. 18 is a cross-sectional view of an intermediate stage of forming a high-k dielectric layer over the structure of FIG. 17 during the formation of the semiconductor device in accordance with some embodiments of the present disclosure.

FIG. 19 is a cross-sectional view of an intermediate stage of sequentially forming a seed layer and a conductive layer over the high-k dielectric layer during the formation of the semiconductor device in accordance with some embodiments of the present disclosure.

FIG. 20 is a cross-sectional view of an intermediate stage of performing a planarization process on the conductive layer, the seed layer, and the high-k dielectric layer to form a top electrode structure and a high-k dielectric structure during the formation of the semiconductor device in accordance with some embodiments of the present disclosure.

FIG. 21 is a cross-sectional view of an intermediate stage of forming a third dielectric layer over the structure of FIG. 20 during the formation of the semiconductor device in accordance with some embodiments of the present disclosure.

FIG. 22 is a cross-sectional view of an intermediate stage of forming a plurality of conductive plugs in the third dielectric layer of the structure of FIG. 21 during the formation of the semiconductor device in accordance with some embodiments of the present disclosure.

FIG. 23 is a cross-sectional view of an intermediate stage of forming a plurality of openings in the third dielectric layer of the structure of FIG. 22 during the formation of the semiconductor device in accordance with some embodiments of the present disclosure.

FIG. 24 is a cross-sectional view of an intermediate stage of forming an energy-removable layer over the third dielectric layer and the conductive plugs and in the openings of the structure of FIG. 23 during the formation of the semiconductor device in accordance with some embodiments of the present disclosure.

FIG. 25 is a cross-sectional view of an intermediate stage of forming a plurality of energy-removable blocks in the openings of the structure of FIG. 24 during the formation of the semiconductor device in accordance with some embodiments of the present disclosure.

FIG. 26 is a cross-sectional view of an intermediate stage of forming a fourth dielectric layer over the structure of FIG. 25 during the formation of the semiconductor device in accordance with some embodiments of the present disclosure.

FIG. 27 is a cross-sectional view of an intermediate stage of forming a plurality of air gap structures in the third dielectric layer of the structure of FIG. 26 during the formation of the semiconductor device in accordance with some embodiments of the present disclosure.

FIG. 28 is a cross-sectional view of an intermediate stage of forming a mask layer over the structure of FIG. 27 during the formation of the semiconductor device in accordance with some embodiments of the present disclosure.

FIG. 29 is a cross-sectional view of an intermediate stage of forming a plurality of conductive pads over the conductive plugs of the structure of FIG. 28 during the formation of the semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

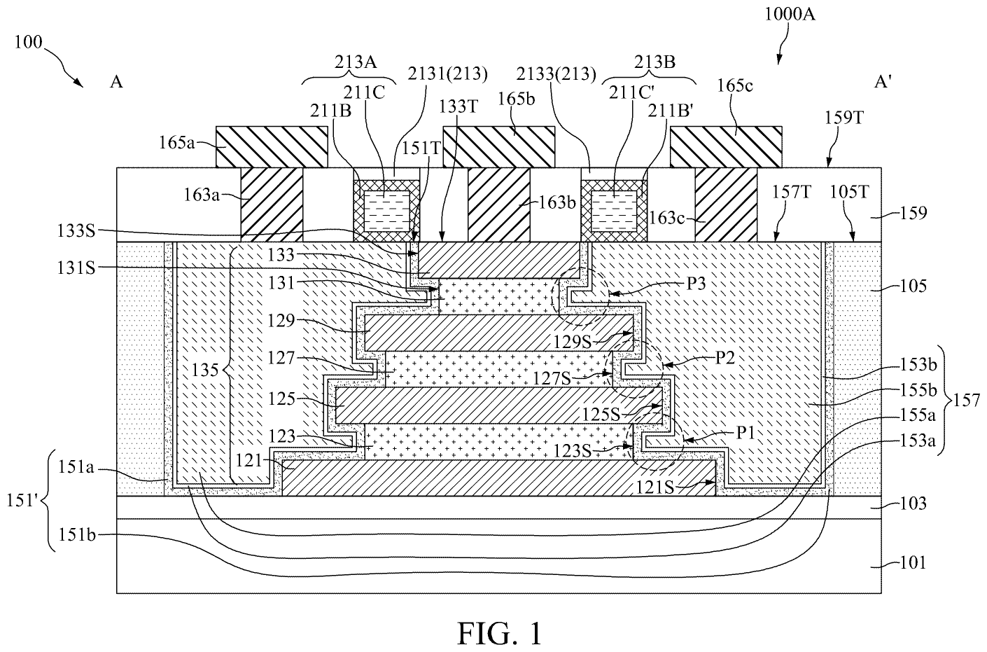

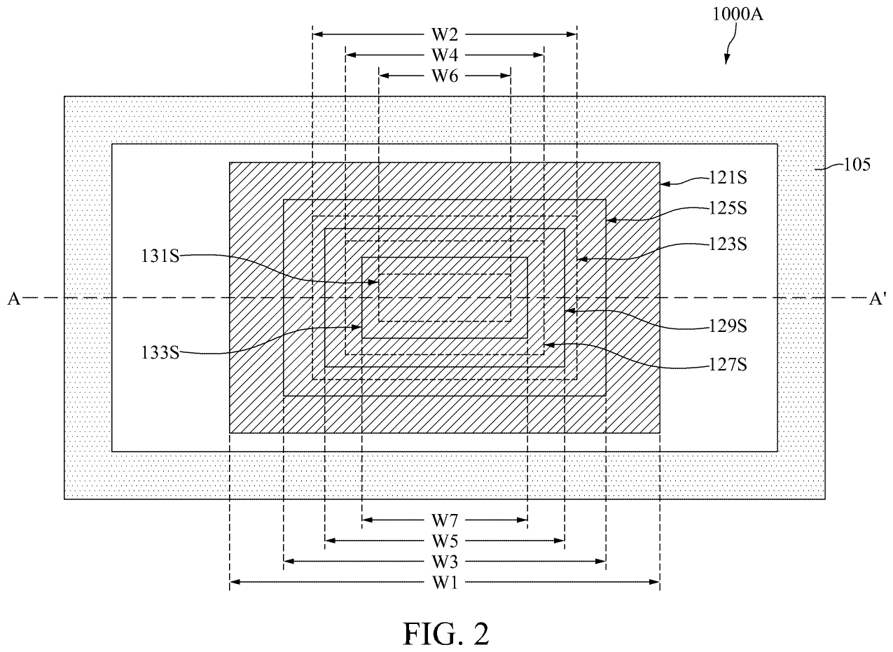

FIG. 1 is a cross-sectional view of a semiconductor device in accordance with some embodiments of the present disclosure, and FIG. 2 is a top view of a portion of the semiconductor device, wherein the cross-sectional view of FIG. 1 is taken along a sectional line A-A′ in FIG. 2.

With reference to FIG. 1, in accordance with some embodiments, the semiconductor device 100 comprises a semiconductor substrate 101, a first dielectric layer 103 disposed over the semiconductor substrate 101, and a bottom electrode structure 135 disposed over the first dielectric layer 103. In some embodiments, the bottom electrode structure 135 includes a first metal layer 121, a second metal layer 123 disposed over the first metal layer 121, a third metal layer 125 disposed over the second metal layer 123, a fourth metal layer 127 disposed over the third metal layer 125, a fifth metal layer 129 disposed over the fourth metal layer 127, a sixth metal layer 131 disposed over the fifth metal layer 129, and a seventh metal layer 133 disposed over the sixth metal layer 131. In some embodiments, the first metal layer 121, the third metal layer 125, the fifth metal layer 129, and the seventh metal layer 133 include a first metal material, and the second metal layer 123, the fourth metal layer 127, and the sixth metal layer 131 include a second metal material different from the first metal material.

In some embodiments, the semiconductor device 100 also includes a high-k dielectric structure 151′ disposed over the first dielectric layer 103 and on opposite sidewalls of the bottom electrode structure 135. In some embodiments, the high-k dielectric structure 151′ includes high-k dielectric portions 151a and 151b covering and in direct contact with the sidewalls 121S, 123S, 125S, 127S, 129S, 131S and 133S of the first metal layer 121, the second metal layer 123, the third metal layer 125, the fourth metal layer 127, the fifth metal layer 129, the sixth metal layer 131 and the seventh metal layer 133. In some embodiments, the opposite sidewalls of the bottom electrode structure 135 (i.e., the sidewalls 121S, 123S, 125S, 127S, 129S, 131S and 133S) collectively form a step-shaped profile.

In some embodiments, the semiconductor device 100 further comprises a top electrode structure 157 laterally surrounding the bottom electrode structure 135 and separated from the bottom electrode structure 135 by the high-k dielectric structure 151′. In some embodiments, the top electrode structure 157 includes seed portions 153a, 153b and conductive portions 155a, 155b. The conductive portions 155a and 155b are disposed over and surrounded by the seed portions 153a and 153b, respectively, as shown in FIG. 1 in accordance with some embodiments.

In some embodiments, the semiconductor device 100 further comprises a second dielectric layer 105 disposed over the first dielectric layer 103 and surrounding the bottom electrode structure 135, the high-k dielectric structure 151′ and the top electrode structure 157. In some embodiments, the first dielectric layer 103 is separated from the top electrode structure 157 by the high-k dielectric structure 151′. In some embodiments, the second dielectric layer 105 is laterally separated from the top electrode structure 157 by the high-k dielectric structure 151′. In some embodiments, a top surface 105T of the second dielectric layer 105, a top surface 133T of the bottom electrode structure 135 (i.e., a top surface 133T of the topmost metal layer in the bottom electrode structure 135), a top surface 151T of the high-k dielectric structure 151', and a top surface 157T of the top electrode structure 157 are substantially coplanar with each other. Within the context of this disclosure, the word “substantially” means preferably at least 90%, more preferably 95%, even more preferably 98%, and most preferably 99%.

In some embodiments, the semiconductor device 100 comprises a third dielectric layer 159 disposed over the second dielectric layer 105 and covering the bottom electrode structure 135, the high-k dielectric structure 151', and the top electrode structure 157. In some embodiments, a plurality of conductive plugs 163a, 163b, 163c and a plurality of air gap structures 213A, 213B are disposed in the third dielectric layer 159, and a plurality of conductive pads 165a, 165b, 165c are disposed over the conductive plugs 163a, 163b, 163c, respectively. In some embodiments, the conductive pad 165a is electrically connected to the conductive portion 155a of the top electrode structure 157 through the conductive plug 163a, the conductive pad 165b is electrically connected to the bottom electrode structure 135 through the conductive plug 163b, and the conductive pad 165c is electrically connected to the conductive portion 155b of the top electrode structure 157 through the conductive plug 163c. In some embodiments, the air gap structure 213A comprises an air gap 211C enclosed by a liner layer 211B and is disposed between the conductive plug 163a and the conductive plug 163b, and the air gap structure 213B comprises an air gap 211C′ enclosed by a liner layer 211B′ and is disposed between the conductive plug 163b and the conductive plug 163c. In some embodiments, a portion 2131 of a fourth dielectric layer 213 is disposed over the air gap structure 213A and between the conductive plug 163a and the conductive plug 163b, and a portion 2133 of the fourth dielectric layer 213 is disposed over the air gap structure 213B and between the conductive plug 163b and the conductive plug 163c. The portion 2131 of the fourth dielectric layer 213 is separated from the bottom electrode 135 by the air gap 211C, and the portion 2133 of the fourth dielectric layer 213 is separated from the bottom electrode 135 by the air gap 211C'.

FIG. 2 is a top view of the second dielectric layer 105 and the bottom electrode structure 135 of the semiconductor device 100 in accordance with some embodiments of the present disclosure. The sidewalls 121S, 123S, 125S, 127S, 129S, 131S and 133S of the first metal layer 121, the second metal layer 123, the third metal layer 125, the fourth metal layer 127, the fifth metal layer 129, the sixth metal layer 131 and the seventh metal layer 133 are shown in FIG. 2.

Moreover, with reference to FIG. 2, the first metal layer 121 has a first width W1, the second metal layer 123 has a second width W2, the third metal layer 125 has a third width W3, the fourth metal layer 127 has a fourth width W4, the fifth metal layer 129 has a fifth width W5, the sixth metal layer 131 has a sixth width W6, and the seventh metal layer 133 has a seventh width W7. In some embodiments, the first width W1 is greater than the third width W3, the third width W3 is greater than the fifth width W5, and the fifth width W5 is greater than the seventh width W7. In some embodiments, the second width W2 is greater than the fourth width W4, and the fourth width W4 is greater than the sixth width W6.

In addition, in accordance with some embodiments, the third width W3 is greater than the second width W2, the fifth width W5 is greater than the fourth width W4, and the seventh width W7 is greater than the sixth width W6.

Embodiments of the semiconductor device 100 with the bottom electrode 135 having step-shaped sidewalls (i.e., the sidewalls 121S, 123S, 125S, 127S, 129S, 131S and 133S) and a method of preparing the same are provided in the disclosure. Since the sidewalls of the bottom electrode structure 135 comprise step-shaped sidewalls, a capacitor formed by the bottom electrode structure 135, the high-k dielectric structure 151′, and the top electrode structure 157 can exhibit an effective area greater than those in the prior art with a particular footprint area, and a capacitance per unit area can be increased. As a result, a performance of the semiconductor device 100 is improved.

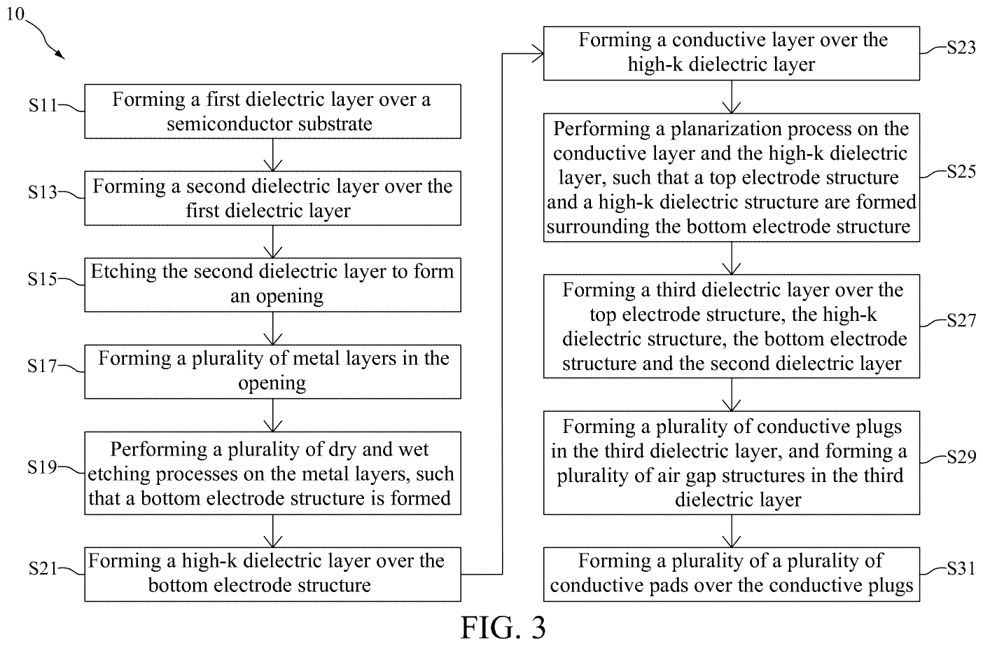

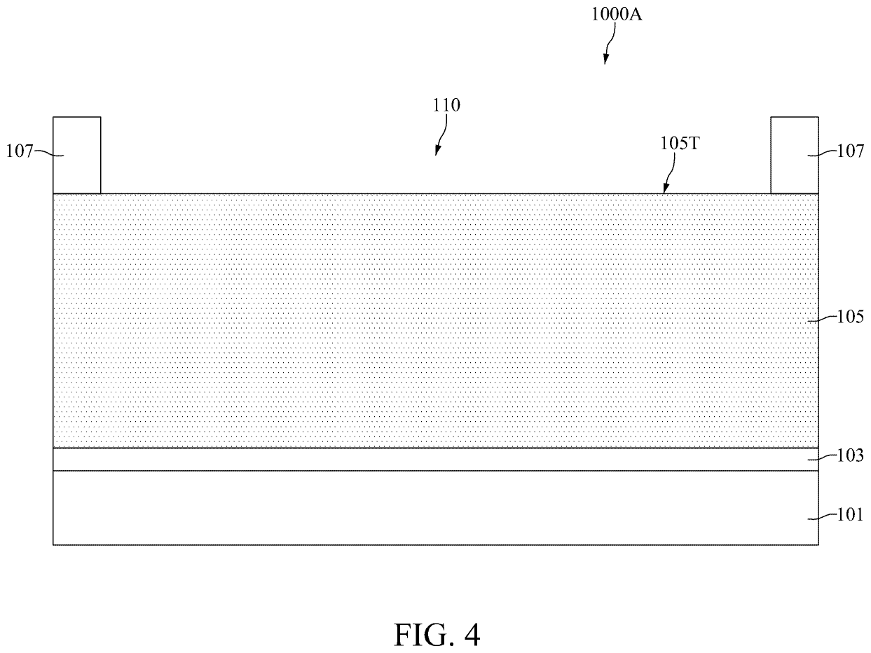

FIG. 3 is a flow diagram of a method 10 of preparing the semiconductor device 100, wherein the method 10 includes steps S11, S13, S15, S17, S19, S21, S23, S25, S27, S29 and S31 in accordance with some embodiments of the present disclosure. The steps S11 to S31 of the method 10 are described with reference to FIGS. 4 to 29.

FIGS. 4 to 29 are cross-sectional views of intermediate stages during the formation of the semiconductor device 100 in accordance with some embodiments of the present disclosure. With reference to FIG. 4, a semiconductor substrate 101 is provided. The semiconductor substrate 101 may comprise a package substrate, an interposer, a printed circuit board (PCB), and/or another circuit carrier that is capable of carrying integrated circuits (IC).

The semiconductor substrate 101 may include various passive and active microelectronic devices, such as resistors, capacitors, inductors, diodes, p-type field-effect transistors (pFETs), n-type field-effect transistors (nFETs), metal-oxide-semiconductor field-effect transistors (MOSFETs), complementary metal-oxide-semiconductor (CMOS) transistors, bipolar junction transistors (BJTs), laterally diffused MOS (LDMOS) transistors, high voltage transistors, high frequency transistors, fin field-effect transistors (FinFETs), other suitable integrated circuit (IC) components, or a combination thereof.

Moreover, the semiconductor substrate 101 may include various material layers (e.g., dielectric layers, semiconductor layers, and/or conductive layers) configured to form IC features (e.g., doped regions, isolation features, gate features, source/drain features, interconnect features, other features, or a combination thereof). The semiconductor substrate 101 is simplified for clarity of discussion. It should be noted that additional features can be added in the semiconductor substrate 101, and some of the features described below can be replaced, modified, or eliminated in other embodiments.

Still referring to FIG. 4, in accordance with some embodiments, a first dielectric layer 103 and a second dielectric layer 105 are formed over the semiconductor substrate 101. The respective steps are illustrated as the steps S11 and S13 in the method 10 shown in FIG. 3. Next, a patterned mask 107 with an opening 110 is formed over the second dielectric layer 105. In some embodiments, a top surface 105T of the second dielectric layer 105 is exposed by the opening 110.

In some embodiments, the first dielectric layer 103 includes silicon dioxide (SiO₂), and the second dielectric layer 105 includes silicon nitride (SiN). However, such materials are merely exemplary. In some embodiments, other suitable materials may alternatively be used to form the first dielectric layer 103 and the second dielectric layer 105. In some embodiments, the second dielectric layer 105 and the patterned mask 107 include different materials such that etching characteristics can be different in subsequent etching processes.

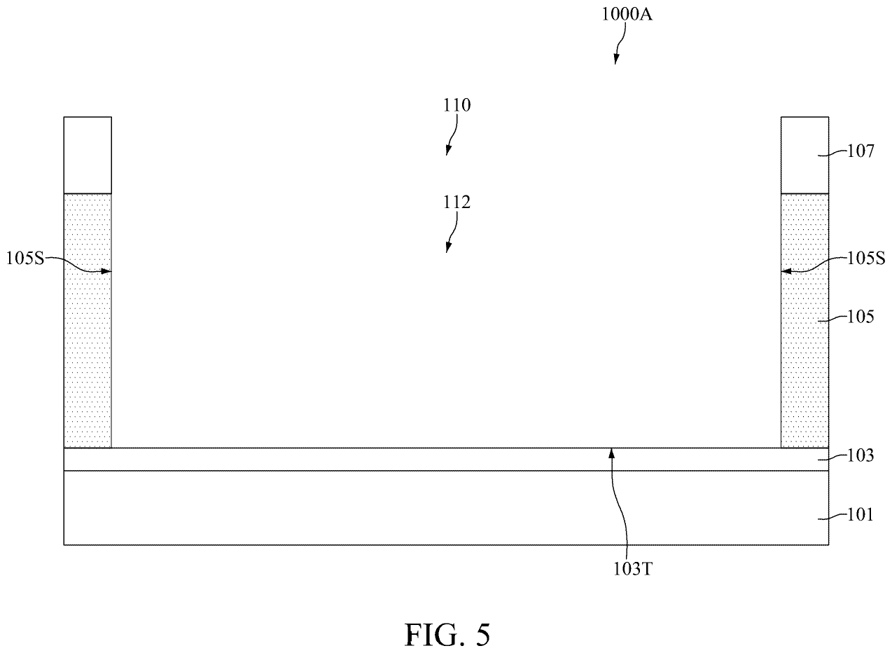

Next, with reference to FIG. 5, in accordance with some embodiments, an etching process is performed using the patterned mask 107 as a mask, such that an opening 112 is formed in the second dielectric layer 105. The respective step is illustrated as the step S15 in the method 10 shown in FIG. 3. In some embodiments, the opening 112 penetrates through the second dielectric layer 105. A top surface 103T of the first dielectric layer 103 and sidewalls 105S of the second dielectric layer 105 are exposed by the opening 112. In some embodiments, the etching process for forming the opening 112 comprises a wet etching process, a dry etching process, or a combination thereof. After the formation of the opening 112, the patterned mask 107 may be removed.

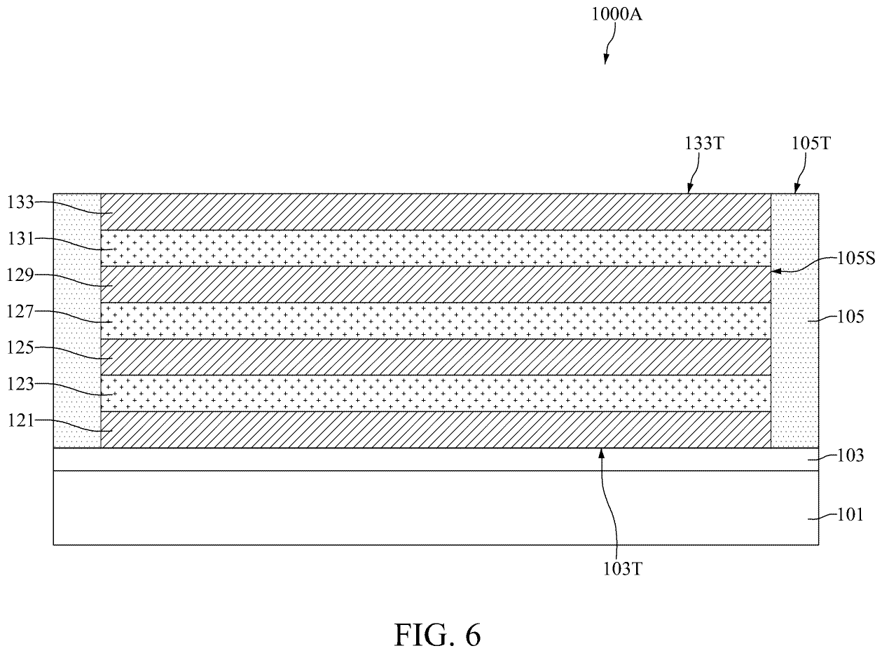

With reference to FIG. 6, in accordance with some embodiments, a first metal layer 121, a second metal layer 123, a third metal layer 125, a fourth metal layer 127, a fifth metal layer 129, a sixth metal layer 131, and a seventh metal layer 133 are sequentially formed in the opening 112. The respective step is illustrated as the step S17 in the method 10 shown in FIG. 3. In some embodiments, the first metal layer 121 is in direct contact with the top surface 103T of the first dielectric layer 103.

Moreover, in some embodiments, the first metal layer 121, the second metal layer 123, the third metal layer 125, the fourth metal layer 127, the fifth metal layer 129, the sixth metal layer 131, and the seventh metal layer 133 adjoin and are in direct contact with the sidewalls 105S of the second dielectric layer 105. In some embodiments, a top surface 133T of the seventh metal layer 133 is substantially coplanar with the top surface 105T of the second dielectric layer 105.

As mentioned above, the first metal layer 121, the third metal layer 125, the fifth metal layer 129, and the seventh metal layer 133 include the first metal material, and the second metal layer 123, the fourth metal layer 127, and the sixth metal layer 131 include the second metal material different from the first metal material. In some embodiments, a melting point of the second metal material is higher than a melting point of the first metal material. In some embodiments, the first metal material includes aluminum (Al), and the second metal material includes copper (Cu). However, such materials are merely exemplary. In some embodiments, other suitable materials may alternatively be used to form the first metal layer 121, the second metal layer 123, the third metal layer 125, the fourth metal layer 127, the fifth metal layer 129, the sixth metal layer 131, and the seventh metal layer 133.

In some embodiments, the first metal layer 121, the second metal layer 123, the third metal layer 125, the fourth metal layer 127, the fifth metal layer 129, the sixth metal layer 131, and the seventh metal layer 133 are formed by a plurality of deposition processes, such as chemical vapor deposition (CVD) processes, physical vapor deposition (PVD) processes, atomic layer deposition (ALD) processes, and/or spin-coating processes. After the deposition processes are performed, a planarization process may be performed to remove excess portions of the metal materials disposed over the top surface 105T of the second dielectric layer 105. The planarization process may be a chemical mechanical polishing (CMP) process.

It should be noted that, although there are four layers of the first metal material (i.e., the first metal layer 121, the third metal layer 125, the fifth metal layer 129 and the seventh metal layer 133) and three layers of the second metal material (i.e., the second metal layer 123, the fourth metal layer 127 and the sixth metal layer 131) shown in FIG. 6, a number of the layers of the first metal material and a number of the layers of the second metal material are not limited to three or four, and depend on demands of manufacturing processes and performance requirements. For example, in accordance with some embodiments, a number of the layers of the first metal material is three and a number of the layers of the second metal material is two. In other words, the sixth metal layer 131 and the seventh metal layer 133 can be omitted. In such case, a top surface of the fifth metal layer 129 is substantially coplanar with the top surface 105T of the second dielectric layer 105. In some other embodiments, a number of the layers of the first metal material and a number of the layers of the second metal material can be more than those of the present embodiment.

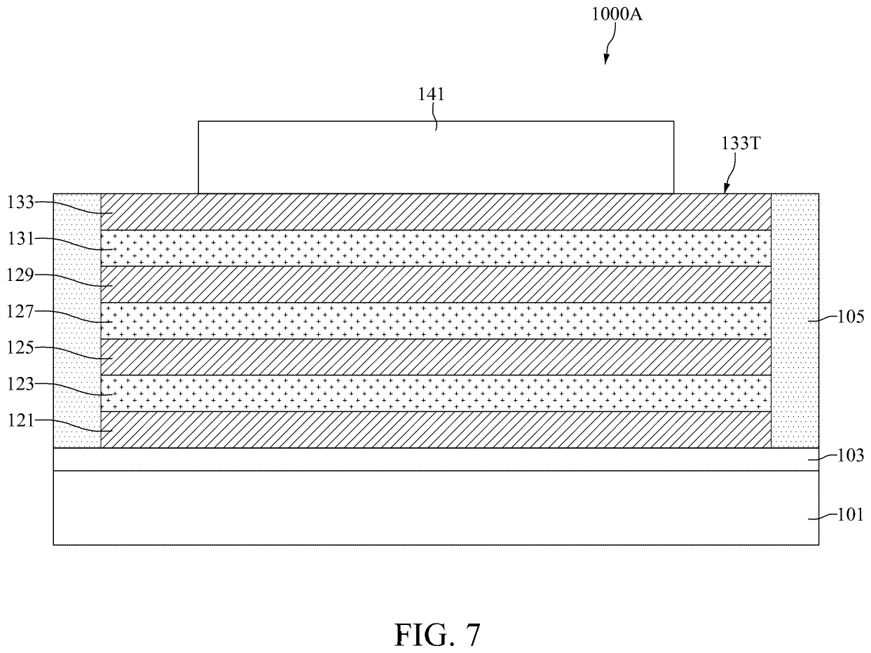

With reference to FIG. 7, in accordance with some embodiments, a patterned photoresist 141 is formed over the top surface 133T of the seventh metal layer 133. In some embodiments, the top surface 133T of the seventh metal layer 133 is partially exposed by the patterned photoresist 141.

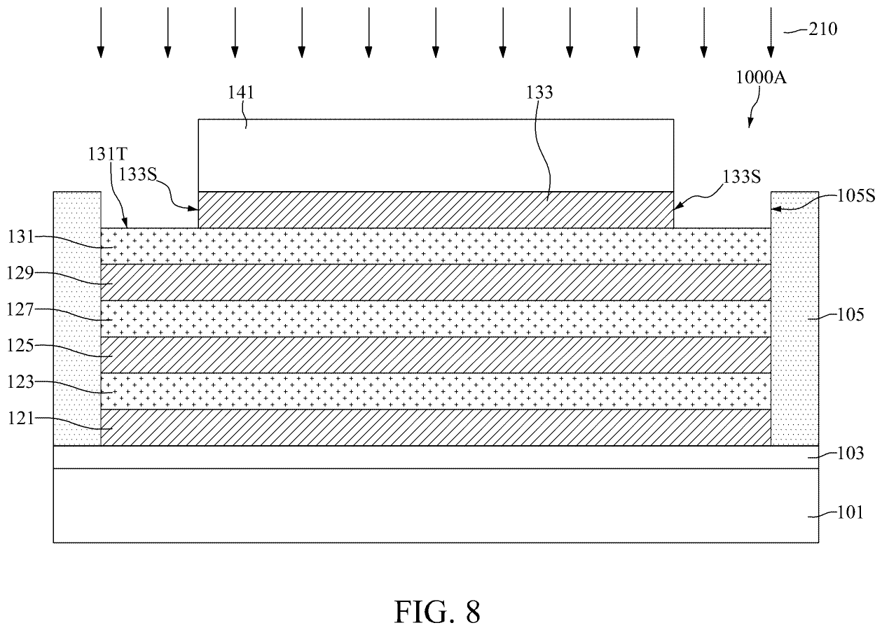

With reference to FIG. 8, in accordance with some embodiments, a dry etching process 210 is performed using the patterned photoresist 141 as a mask to partially remove the seventh metal material 133. In some embodiments, after the dry etching process 210 is performed, sidewalls 133S of the seventh metal layer 133 are exposed. In addition, in accordance with some embodiments, during the dry etching process 210, since the material of the seventh metal layer 133 has an etch characteristic with respect to the material of the sixth metal layer 131, the sixth metal layer 131 remains substantially intact. As a result, after the dry etching process 210 is performed, a top surface 131T of the sixth metal layer 131 and the sidewalls 105S of the second dielectric layer 105 are partially exposed.

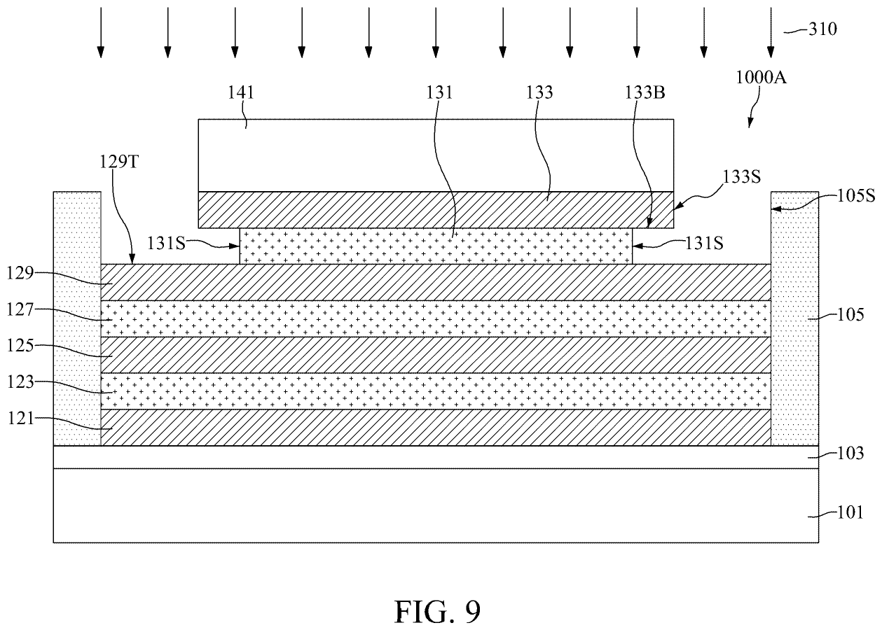

With reference to FIG. 9, in accordance with some embodiments, a wet etching process 310 is performed to partially remove the sixth metal layer 131. During the wet etching process 310, since the material of the sixth metal layer 131 has an etch characteristic with respect to the materials of the seventh metal layer 133 and the fifth metal layer 129, the seventh metal layer 133 and the fifth metal layer 129 remain substantially intact.

In some embodiments, after the wet etching process 310 is performed, sidewalls 131S of the sixth metal layer 131 are exposed. Moreover, in accordance with some embodiments, a bottom surface 133B of the seventh metal layer 133 and a top surface 129T of the fifth metal layer 129 are partially exposed. After the wet etching process 310 is performed, the patterned photoresist 141 can be removed.

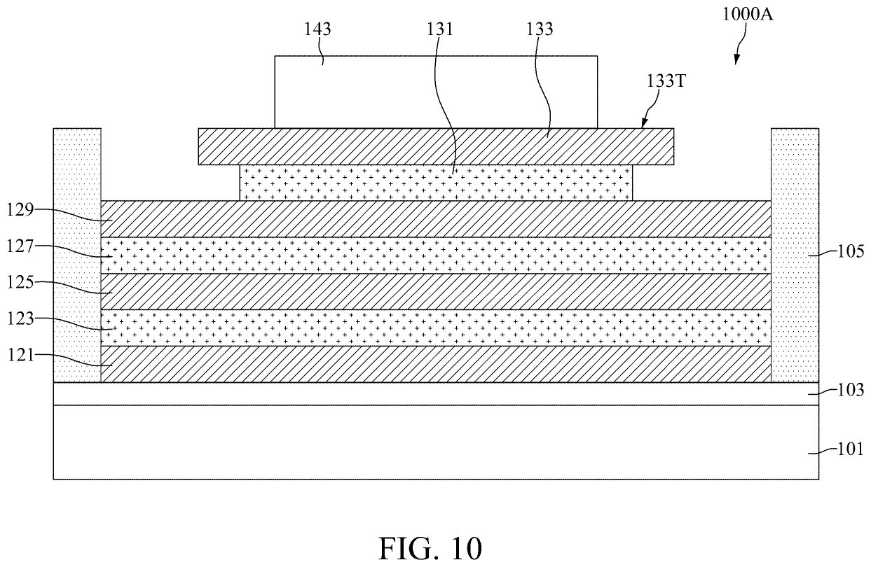

With reference to FIG. 10, in accordance with some embodiments, a patterned photoresist 143 is formed over the top surface 133T of the seventh metal layer 133. In some embodiments, the top surface 133T of the seventh metal layer 133 is partially exposed by the patterned photoresist 143.

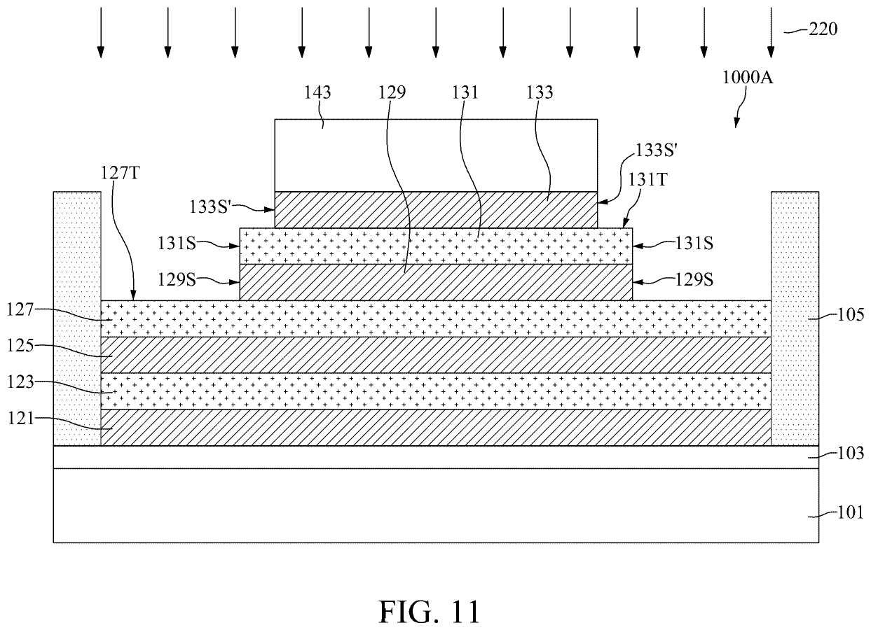

With reference to FIG. 11, in accordance with some embodiments, a dry etching process 220 is performed using the patterned photoresist 143 as a mask to partially remove the seventh metal layer 133 and the fifth metal layer 129. In some embodiments, after the dry etching process 220 is performed, sidewalls 133S′ of the seventh metal layer 133 and sidewalls 129S of the fifth metal layer 129 are exposed. In addition, during the dry etching process 220, since the materials of the seventh metal layer 133 and the fifth metal layer 129 have etch characteristics with respect to the materials of the sixth metal layer 131 and the fourth metal layer 127, the sixth metal layer 131 and the fourth metal layer 127 remain substantially intact. As a result, after the dry etching process 220 is performed, a top surface 127T of the fourth metal layer 127 is partially exposed.

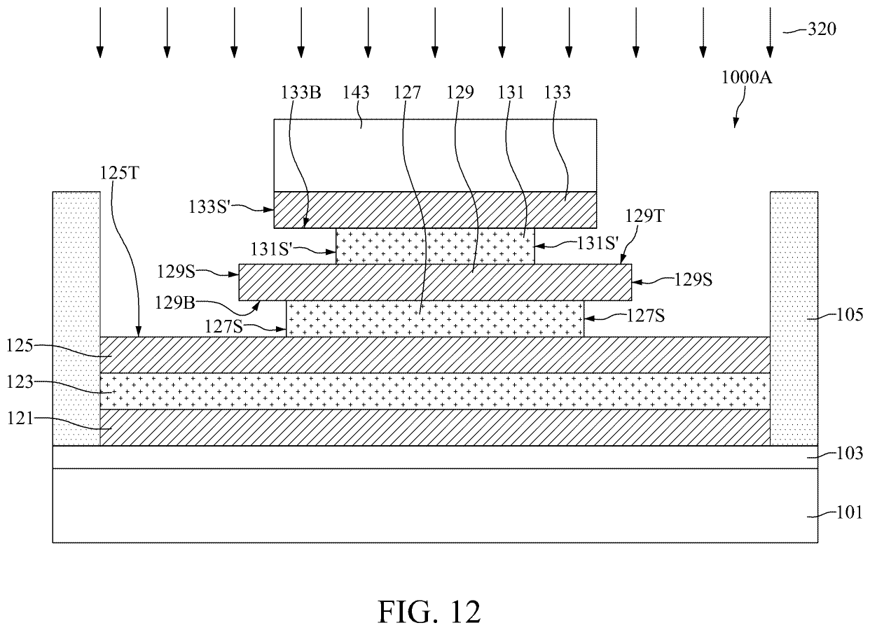

With reference to FIG. 12, in accordance with some embodiments, a wet etching process 320 is performed to partially remove the sixth metal layer 131 and the fourth metal layer 127. During the wet etching process 320, since the materials of the sixth metal layer 131 and the fourth metal layer 127 have etch characteristics with respect to materials of the seventh metal layer 133, the fifth metal layer 129 and the third metal layer 125, the seventh metal layer 133, the fifth metal layer 129 and the third metal layer 125 remain substantially intact.

In some embodiments, after the wet etching process 320 is performed, sidewalls 131S′ of the sixth metal layer 131 and sidewalls 127S of the fourth metal layer 127 are exposed. Moreover, after the wet etching process 320 is performed, the bottom surface 133B of the seventh metal layer 133, a bottom surface 129B of the fifth metal layer 129, and the top surface 125T of the third metal layer 125 are partially exposed. After the wet etching process 320 is performed, the patterned photoresist 143 can be removed.

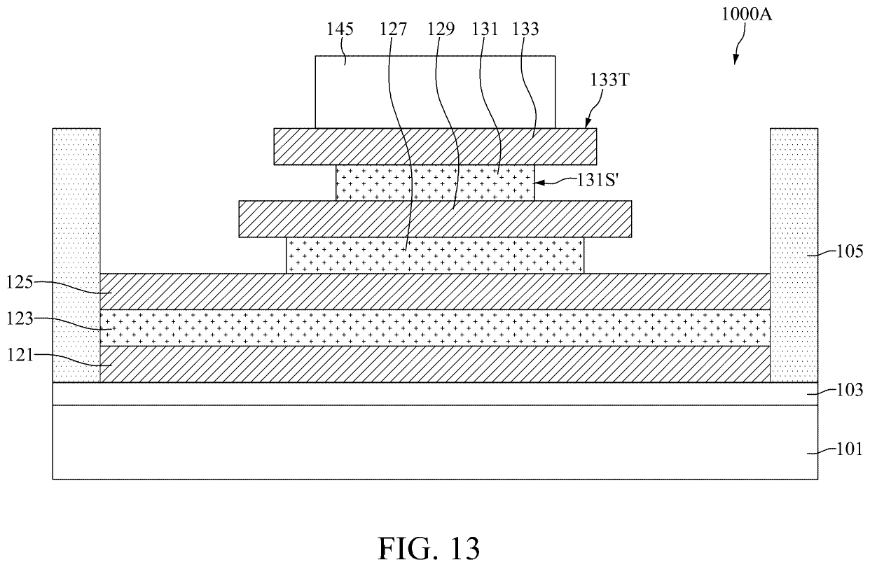

With reference to FIG. 13, in accordance with some embodiments, a patterned photoresist 145 is formed over the top surface 133T of the seventh metal layer 133. In some embodiments, the top surface 133T of the seventh metal layer 133 is partially exposed by the patterned photoresist 145.

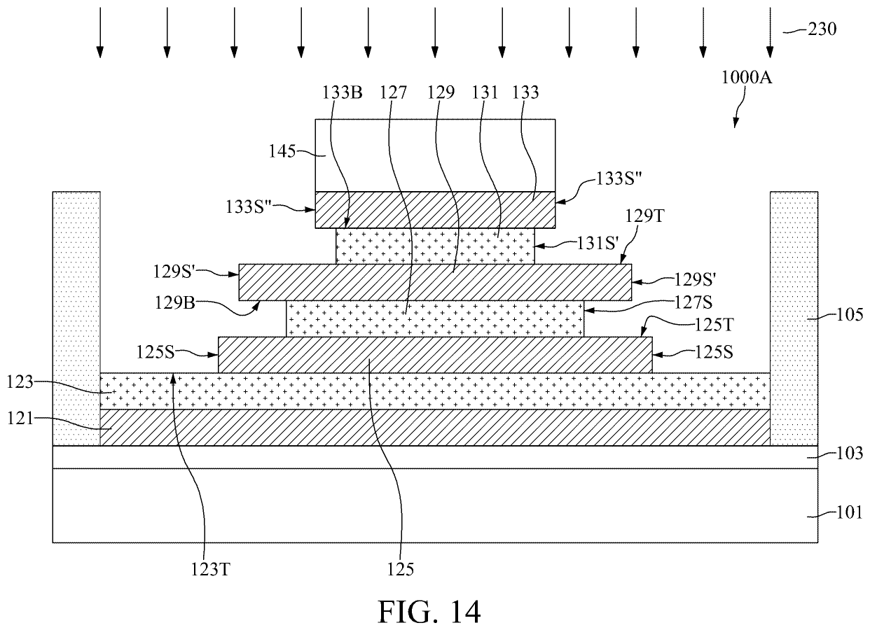

With reference to FIG. 14, in accordance with some embodiments, a dry etching process 230 is performed using the patterned photoresist 145 as a mask to partially remove the seventh metal layer 133, the fifth metal layer 129 and the third metal layer 125. In some embodiments, after the dry etching process 230 is performed, sidewalls 133S″ of the seventh metal layer 133, sidewalls 129S′ of the fifth metal layer 129, and sidewalls 125S of the third metal layer 125 are exposed. In addition, during the dry etching process 230, since the materials of the seventh metal layer 133, the fifth metal layer 129 and the third metal layer 125 have etch characteristics with respect to materials of the sixth metal layer 131, the fourth metal layer 127 and the second metal layer 123, the sixth metal layer 131, the fourth metal layer 127 and the second metal layer 123 remain substantially intact. As a result, after the dry etching process 230 is performed, a top surface 123T of the second metal layer 123 is partially exposed.

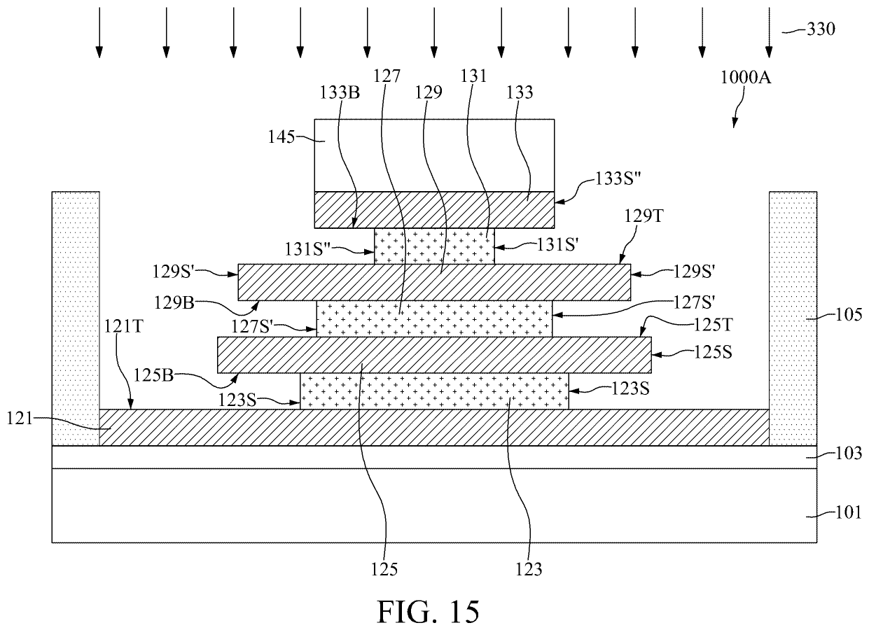

With reference to FIG. 15, in accordance with some embodiments, a wet etching process 330 is performed to partially remove the sixth metal layer 131, the fourth metal layer 127 and the second metal layer 123. During the wet etching process 330, since the materials of the sixth metal layer 131, the fourth metal layer 127 and the second metal layer 123 have etch characteristics with respect to materials of the seventh metal layer 133, the fifth metal layer 129, the third metal layer 125 and the first metal layer 121, the seventh metal layer 133, the fifth metal layer 129, the third metal layer 125 and the first metal layer 121 remain substantially intact.

In some embodiments, after the wet etching process 330 is performed, sidewalls 131S″ of the sixth metal layer 131, sidewalls 127S′ of the fourth metal layer 127, and sidewalls 123S of the second metal layer 123 are exposed. Moreover, in accordance with some embodiments, the bottom surface 133B of the seventh metal layer 133, the bottom surface 129B of the fifth metal layer 129, the bottom surface 125B of the third metal layer 125, and a top surface 121T of the first metal layer 121 are partially exposed. After the wet etching process 330 is performed, the patterned photoresist 145 can be removed.

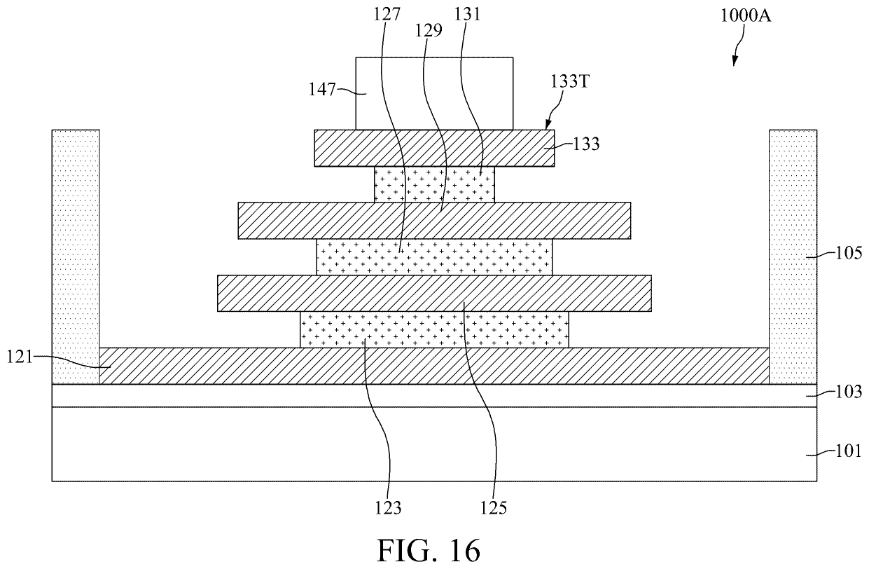

With reference to FIG. 16, in accordance with some embodiments, a patterned photoresist 147 is formed over the top surface 133T of the seventh metal layer 133. In some embodiments, the top surface 133T of the seventh metal layer 133 is partially exposed by the patterned photoresist 147.

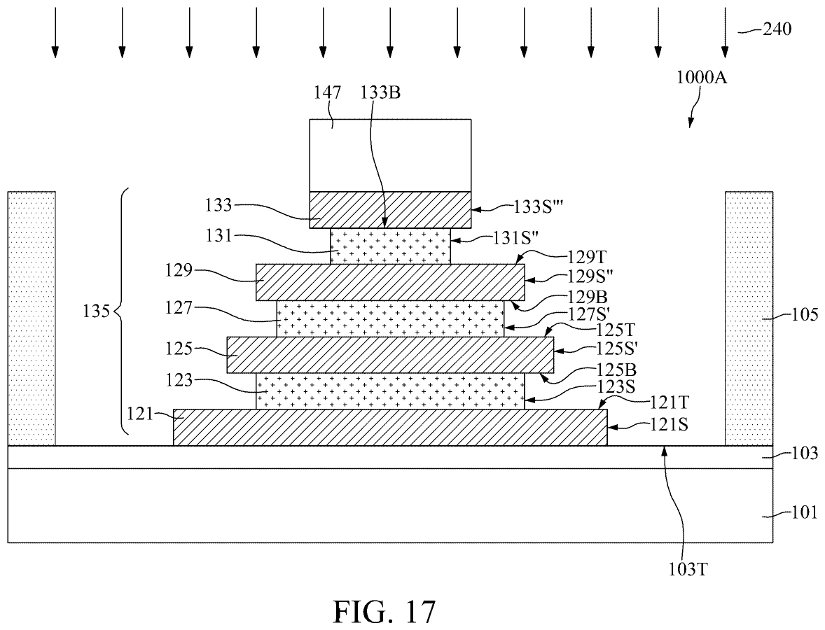

With reference to FIG. 17, in accordance with some embodiments, a dry etching process 240 is performed using the patterned photoresist 147 as a mask to partially remove the seventh metal layer 133, the fifth metal layer 129, the third metal layer 125 and the first metal layer 121. In some embodiments, after the dry etching process 240 is performed, sidewalls 133S′″ of the seventh metal layer 133, sidewalls 129S″ of the fifth metal layer 129, sidewalls 125S′ of the third metal layer 125, and sidewalls 121S of the first metal layer 121 are exposed.

In addition, during the dry etching process 240, since the materials of the seventh metal layer 133, the fifth metal layer 129, the third metal layer 125 and the first metal layer 121 have etch characteristics with respect to materials of the sixth metal layer 131, the fourth metal layer 127 and the second metal layer 123, the sixth metal layer 131, the fourth metal layer 127 and the second metal layer 123 remain substantially intact. In some embodiments, after the dry etching process 240 is performed, the top surface 103T of the first dielectric layer 103 is partially exposed.

After the dry etching process 240 is performed, a bottom electrode 135 including the first metal layer 121, the second metal layer 123, the third metal layer 125, the fourth metal layer 127, the fifth metal layer 129, the sixth metal layer 131 and the seventh metal layer 133 is obtained. The respective step is illustrated as the step S19 in the method 10 shown in FIG. 3. In some embodiments, the sidewalls of the bottom electrode structure 135 are step-shaped. After the top surface 103T of the first dielectric layer 103 is partially exposed, the patterned mask 147 may be removed.

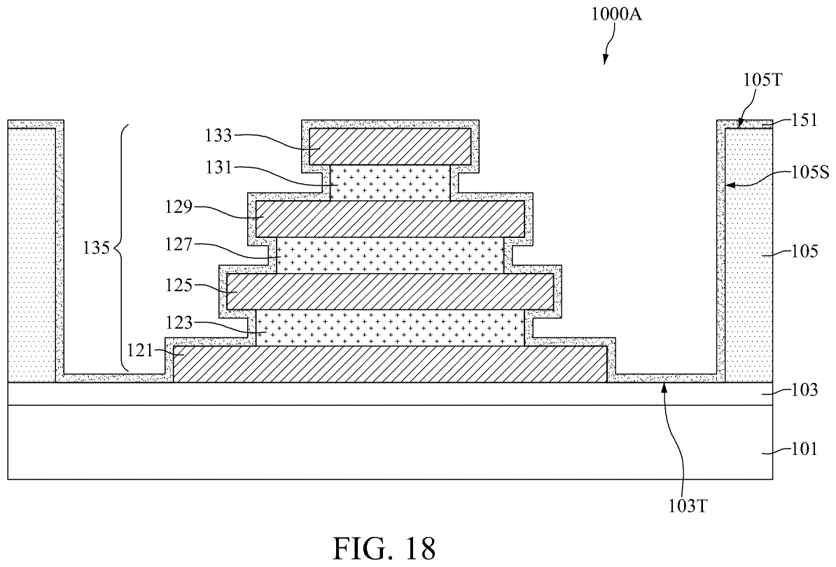

With reference to FIG. 18, in accordance with some embodiments, a high-k dielectric layer 151 is conformally formed over the structure of FIG. 17. In some embodiments, the bottom electrode structure 135 is covered by the high-k dielectric layer 151. Moreover, in some embodiments, the top surface 103T of the first dielectric layer 103 and the sidewalls 105S and the top surface 105T of the second dielectric layer 105 are covered by and in direct contact with the high-k dielectric layer 151. The respective step is illustrated as the step S21 in the method 10 shown in FIG. 3.

In some embodiments, the high-k dielectric layer 151 includes a high-k dielectric material such as hafnium oxide, lanthanum oxide, aluminum oxide, zirconium oxide, or the like. In addition, the high-k dielectric layer 151 may be deposited by a conformal deposition process, such as a CVD process, an ALD process, a plasma-enhanced CVD (PECVD) process, another suitable process, or a combination thereof.

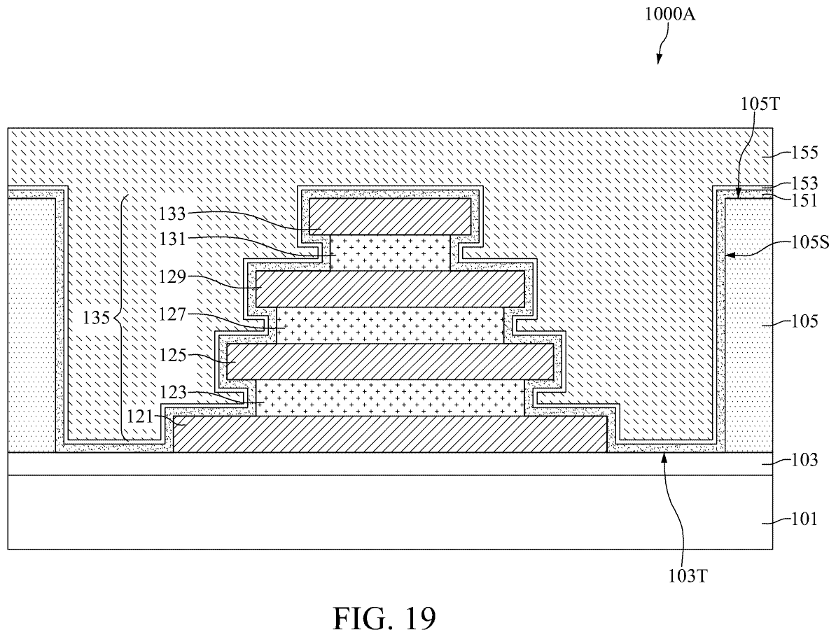

With reference to FIG. 19, in accordance with some embodiments, a seed layer 153 and a conductive layer 155 are sequentially formed over the high-k dielectric layer 151. The respective step is illustrated as the step S23 in the method 10 shown in FIG. 3. In some embodiments, the seed layer 153 includes an alloy of titanium (Ti) and copper (Cu), and may be formed by a CVD process, a PVD process, a sputtering process, a plating process, or another suitable process. In some embodiments, the conductive layer 155 includes a low resistivity conductive material, such as copper (Cu). In some other embodiments, the conductive layer 155 includes tungsten (W), aluminum (Al), titanium (Ti), tantalum (Ta), gold (Au), silver (Ag), a combination thereof, or another suitable conductive material. The conductive layer 155 may be formed by a CVD process, a PVD process, a sputtering process, a plating process, or another suitable process.

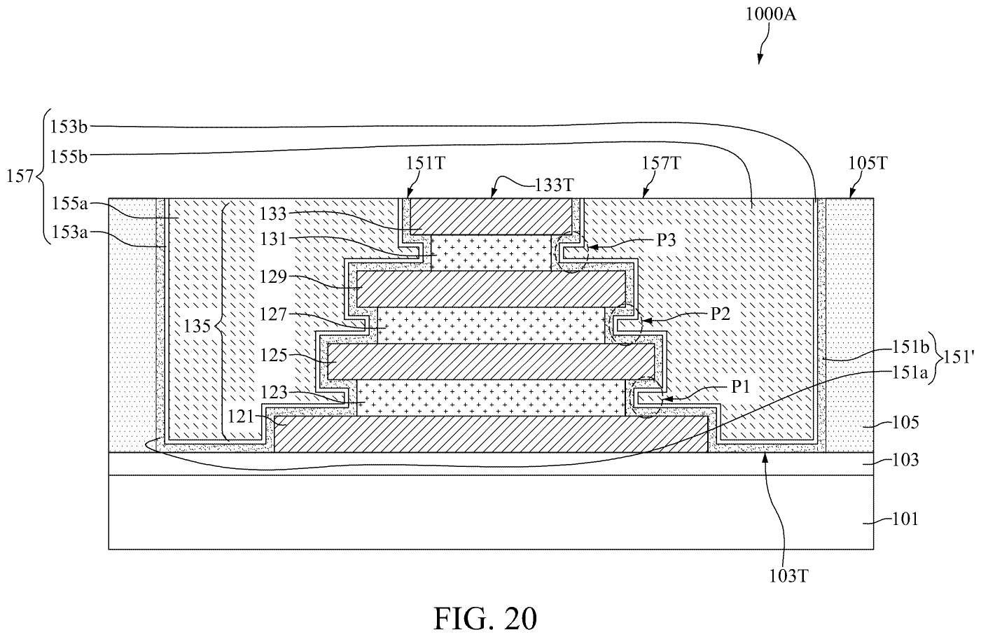

With reference to FIG. 20, in accordance with some embodiments, after the formation of the conductive layer 155, a planarization process is performed on the conductive layer 155, the seed layer 153 and the high-k dielectric layer 151 to form a top electrode structure 157 and a high-k dielectric structure 151′. The planarization process may include a CMP process, which removes excess portions of the conductive layer 155, the seed layer 153 and the high-k dielectric layer 151 over the top surface 105T of the second dielectric layer 105.

In some embodiments, after the planarization process is performed, remaining portions of the high-k dielectric layer 151 are referred to as high-k dielectric portions 151a and 151b, remaining portions of the seed layer 153 are referred to as seed portions 153a and 153b, and remaining portions of the conductive layer 155 are referred to as conductive portions 155a and 155b. In some embodiments, the high-k dielectric portions 151a and 151b collectively form the high-k dielectric structure 151′. In some embodiments, the seed portions 153a, 153b and the conductive portions 155a, 155b collectively form the top electrode structure 157.

In some embodiments, the top electrode structure 157 has a portion P1 extending between the first metal layer 121 and the third metal layer 125 of the bottom electrode structure 135. In some embodiments, the top electrode structure 157 has a portion P2 extending between the third metal layer 125 and the fifth metal layer 129 of the bottom electrode structure 135. In some embodiments, the top electrode structure 157 has a portion P3 extending between the fifth metal layer 129 and the seventh metal layer 133 of the bottom electrode structure 135.

The top surface 133T of the seventh metal layer 133 is also referred to as the top surface of the bottom electrode structure 135. In some embodiments, after the planarization process is performed, the top surface of the bottom electrode structure 135 is exposed. Moreover, in accordance with some embodiments, the top surface of the bottom electrode structure 135 (i.e., the top surface 133T), a top surface 151T of the high-k dielectric structure 151′, a top surface 157T of the top electrode structure 157, and the top surface 105T of the second dielectric layer 105 are substantially coplanar with each other. The respective step is illustrated as the step S25 in the method 10 shown in FIG. 3.

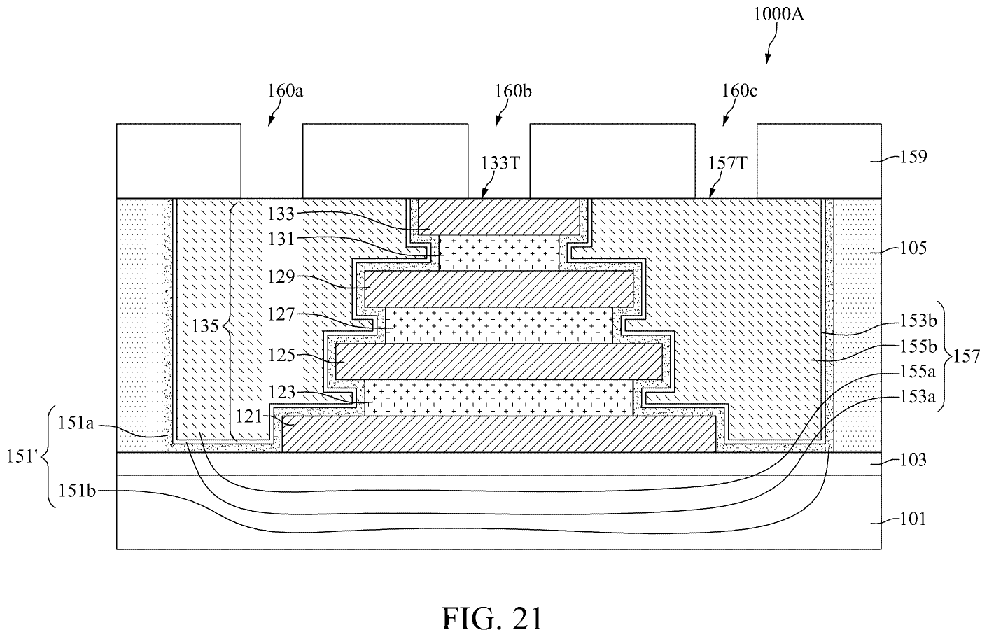

With reference to FIG. 21, in accordance with some embodiments, a third dielectric layer 159 with a plurality of openings 160a, 160b, 160c is formed over the structure of FIG. 20. The respective step is illustrated as the step S27 in the method 10 shown in FIG. 3. In some embodiments, the top surface 157T of the top electrode structure 157 is partially exposed by the openings 160a, 160c, and the top surface 133T of the bottom electrode structure 135 is partially exposed by the opening 160b. In some embodiments, the third dielectric layer 159 includes silicon oxide, silicon nitride, silicon oxynitride, or another suitable dielectric material.

The formation of the third dielectric layer 159 with the openings 160a, 160b, 160c may include depositing the third dielectric layer 159 covering the second dielectric layer 105, the top electrode structure 157 and the bottom electrode structure 135, forming a patterned mask (not shown) over the third dielectric layer 159, performing an etching process on the third dielectric layer 159 using the patterned mask as an etching mask, and removing the patterned mask. In some embodiments, the etching process for forming the openings 160a, 160b, 160c includes a dry etching process, a wet etching process, or a combination thereof.

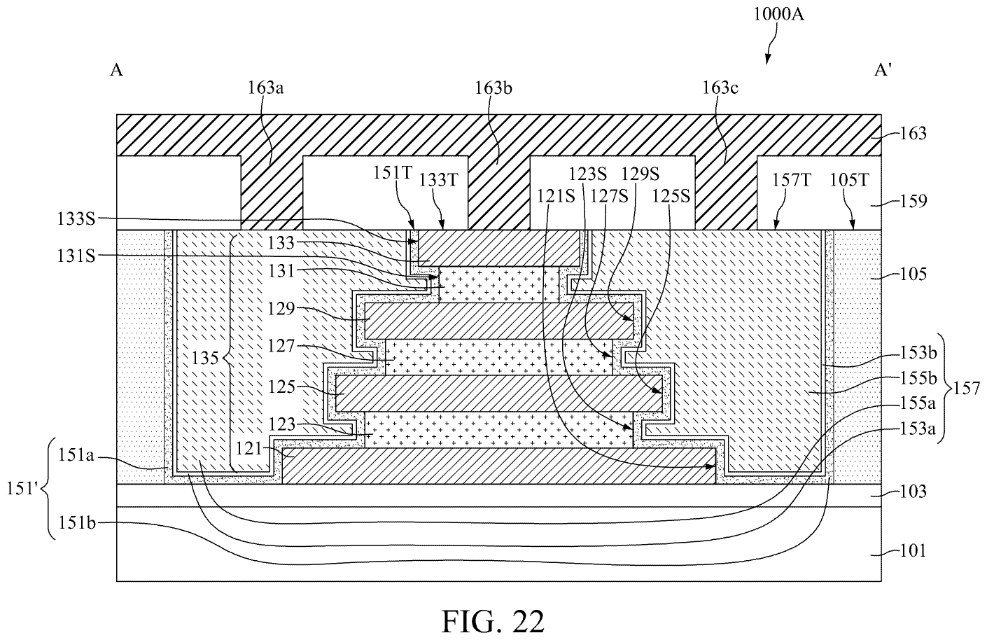

With reference to FIG. 22, in accordance with some embodiments, a conductive material 163 is formed covering the third dielectric layer 159 and filling the openings 160a, 160b, 160c. In some embodiments, the conductive material 163 includes a conductive material, such as copper (Cu), lithium (Li), aluminum (Al), tungsten (W), titanium (Ti), titanium nitride (TiN), tantalum (Ta), tantalum nitride (TaN), or another suitable material. In some embodiments, the conductive material 163 is formed by a deposition process, such as a CVD process, a PVD process, an ALD process, another suitable process, or a combination thereof. After the deposition process is performed, a planarization process may be performed to remove portions of the conductive material 163 over the third dielectric layer 159. The planarization process may include a CMP process.

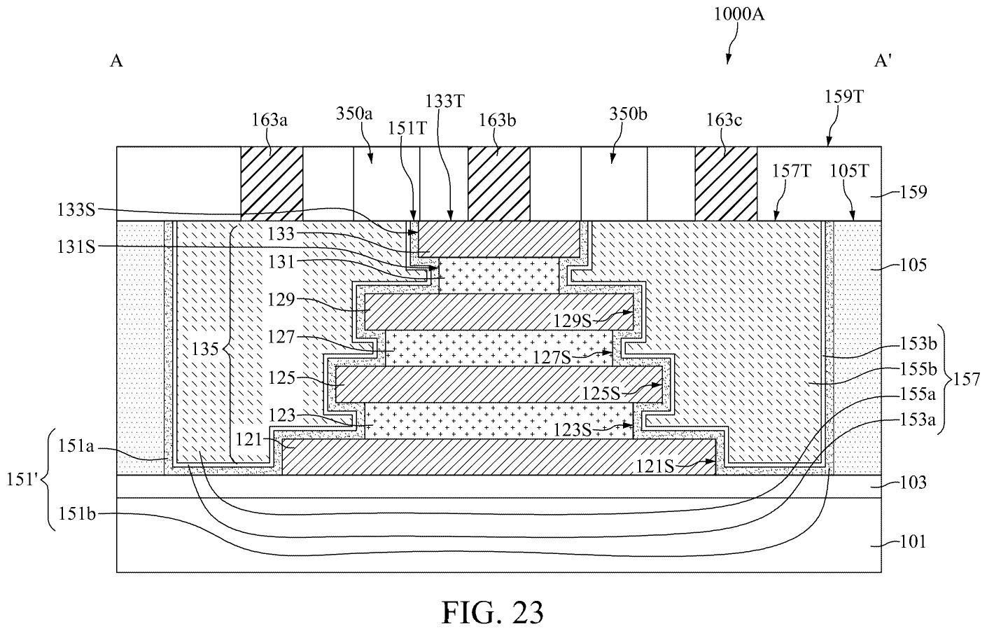

With reference to FIG. 23, in accordance with some embodiments, after the planarization process is performed, a plurality of conductive plugs 163a, 163b, 163c are formed in the openings 160a, 160b, 160c, respectively. Top surfaces of the conductive plugs 163a, 163b, 163c are coplanar with a top surface 159T of the third dielectric layer 159.

Still referring to FIG. 23, in accordance with some embodiments, a plurality of openings 350a, 350b are formed in the third dielectric layer 159, wherein the opening 350a is disposed between the conductive plug 163a and the conductive plug 163b, and the opening 350b is disposed between the conductive plug 163b and the conductive plug 163c. In some embodiments, an etching process using a patterned mask as a mask is performed to form the openings 350a, 350b. In some embodiments, the etching process may be a dry etching process, a wet etching process, or a combination thereof.

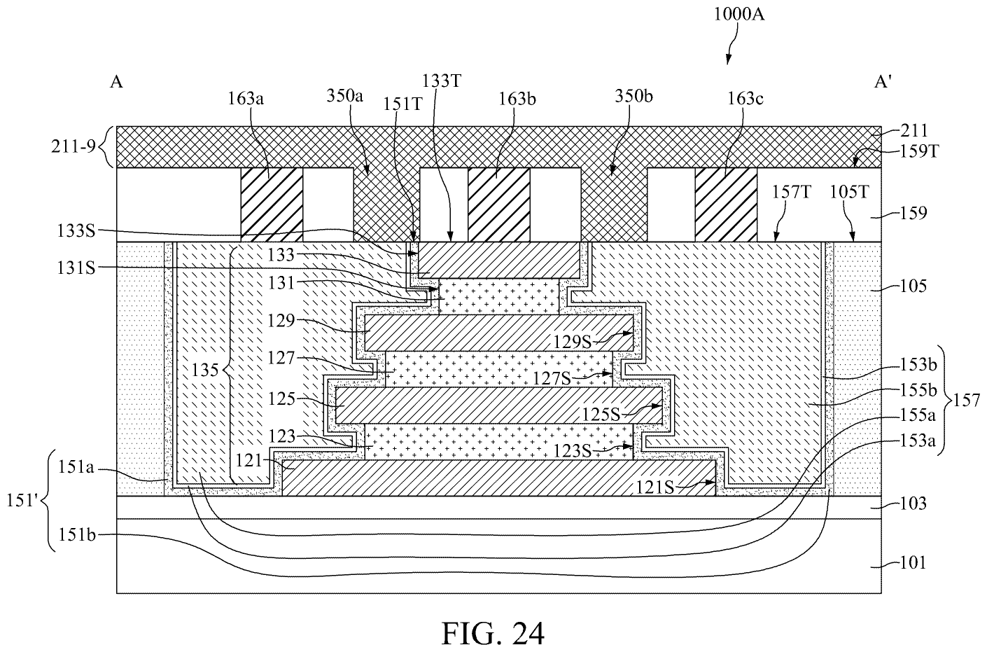

With reference to FIG. 24, in accordance with some embodiments, a deposition process is performed to form an energy-removable layer 211 to cover the conductive plugs 163a, 163b, 163c and the third dielectric layer 159, and to fill the openings 350a, 350b. In some embodiments, the energy-removable layer 211 includes a thermal decomposable material. In some other embodiments, the energy-removable layer 211 includes a photonic decomposable material, an e-beam decomposable material, or another applicable energy-decomposable material. Specifically, in some embodiments, the energy-removable layer 211 includes a base material and a decomposable porogen material that is substantially removed once exposed to an energy source (e.g., heat). In some embodiments, the base material includes hydrogen silsesquioxane (HSQ), methylsilsesquioxane (MSQ), porous polyarylether (PAE), porous SiLK, or porous silicon oxide (SiO₂), and the decomposable porogen material includes a porogen organic compound, which can provide porosity to a space originally occupied by the energy-removable layer 211. In some embodiments, the deposition process may include a CVD process, a PVD process, an ALD process, another suitable process, or a combination thereof. After the deposition process is performed, a planarization process may be performed to remove a portion 211-9 of the energy-removable layer 211 over portions deposited in the openings 350a, 350b, and provide a substantially flat surface for subsequent processing steps. In some embodiments, after the planarization process is performed, the top surfaces of the portions of the energy-removable layer 211 deposited in the openings 350a, 350b are substantially coplanar with the top surface 159T of the third dielectric layer 159.

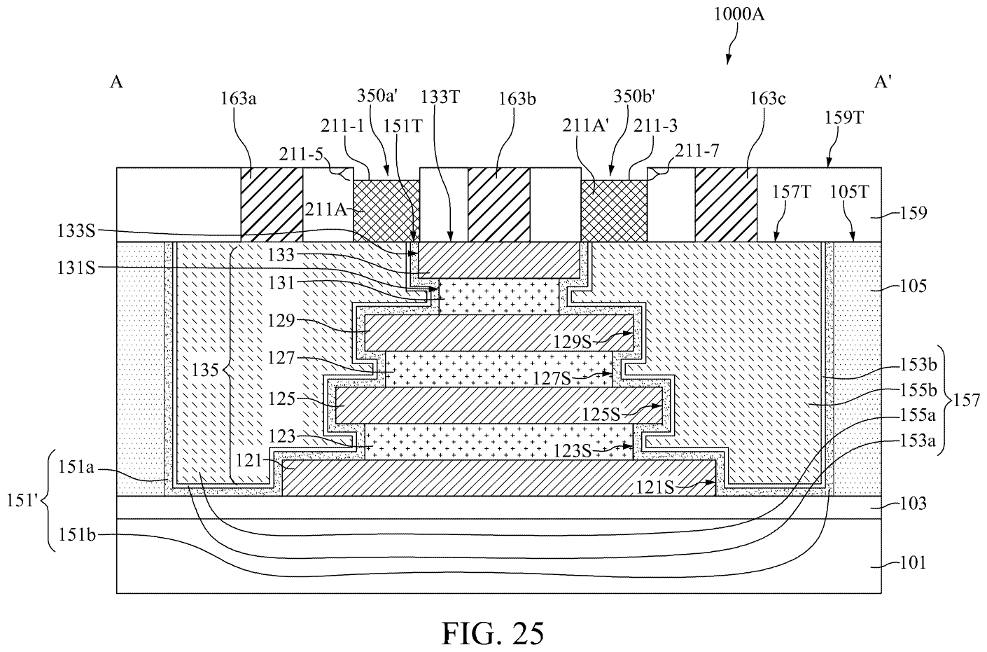

With reference to FIG. 25, in accordance with some embodiments, an etching process is subsequently performed to remove portions 211-5, 211-7 of the energy-removable layer 211 in the openings 350a, 350b. In some embodiments, the etching process may be a dry etching process. After the etching process is performed, a plurality of energy-removable blocks 211A, 211A′ and a plurality of recesses 350a′ and 350b′ are formed in the openings 350a, 350b, respectively. It should be noted that, after the removal of the portions 211-5 and 211-7, top surfaces 211-1 and 211-3 of the energy-removable blocks 211A, 211A′ in the openings 350a, 350b are lower than the top surface 159Tof the third dielectric layer 159.

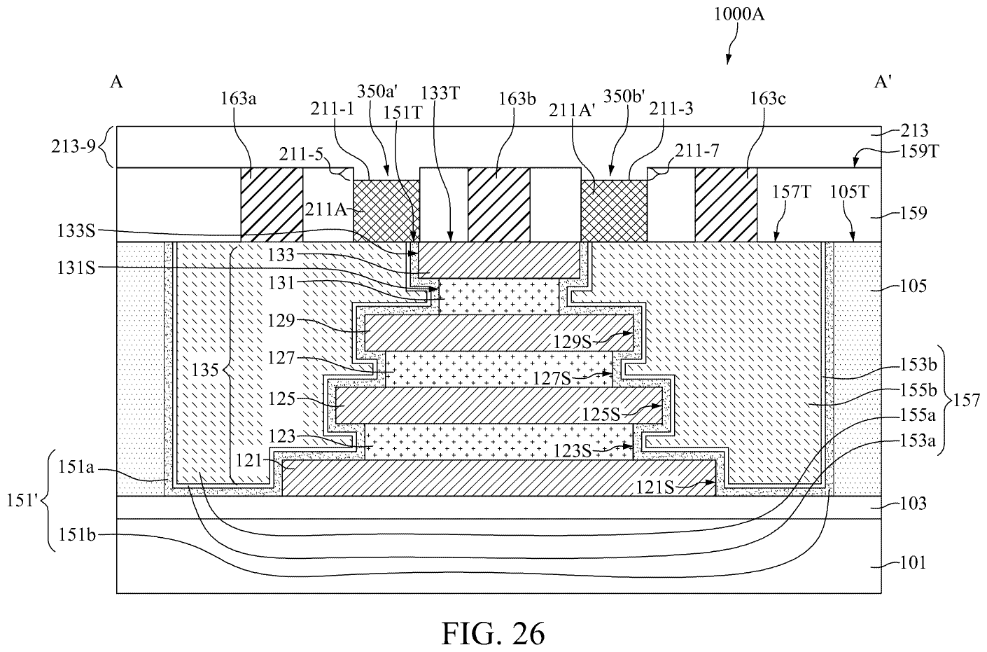

With reference to FIG. 26, in accordance with some embodiments, a deposition process is performed to form a fourth dielectric layer 213 to cover the conductive plugs 163a, 163b, 163c, the energy-removable blocks 211A, 211A′, and the third dielectric layer 159. It should be noted that the recesses 350a, 350b are filled by the fourth dielectric layer 213. In some embodiments, materials of the fourth dielectric layer 213 are same as materials of the third dielectric layer 159. In some embodiments, materials of the fourth dielectric layer 213 are different from the materials of the third dielectric layer 159. In some embodiments, the deposition process may include a CVD process, a PVD process, an ALD process, another suitable process, or a combination thereof. In some embodiments, a planarization process is performed to remove a portion 213-9 of the fourth dielectric layer 213 over the top surface 159T of the third dielectric layer 159, and to provide a substantially flat surface for subsequent processing steps.

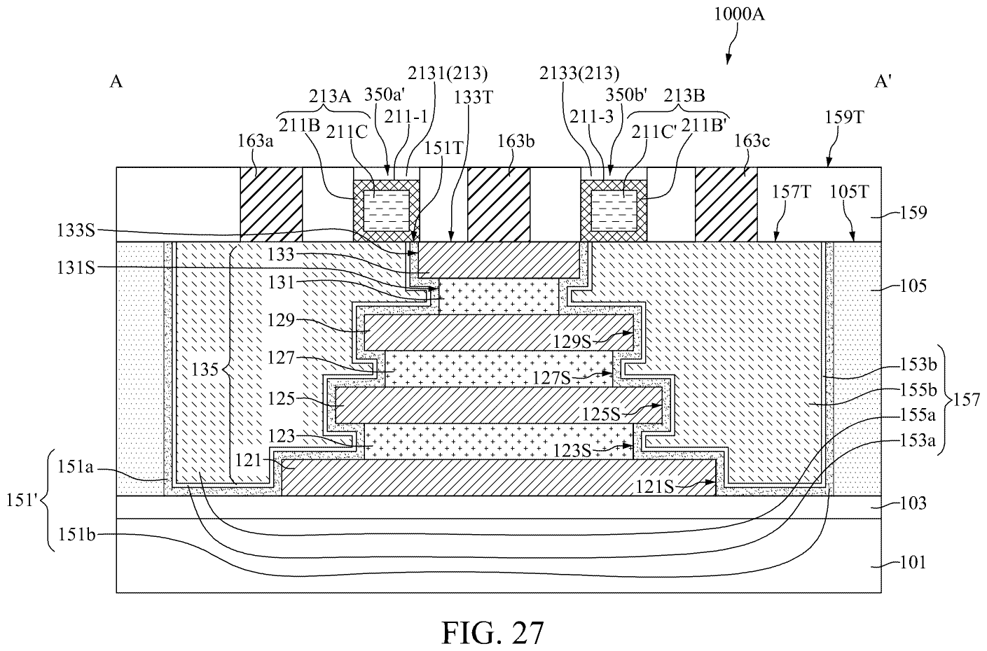

With reference to FIG. 27, in accordance with some embodiments, after the planarization process is performed, remaining portions 2131, 2133 of the fourth dielectric layer 213 are left in place over the energy-removable blocks 211A, 211A′. Subsequently, a thermal treatment process is performed to transform the energy-removable blocks 211A, 211A′ into a plurality of air gap structures 213A, 213B, respectively, wherein the air gap structure 213A comprises an air gap 211C enclosed by a liner 211B, and the air gap structure 213B comprises an air gap 211C′ enclosed by a liner 211B′. In some embodiments, the air gap structures 213A, 213B are sealed by the fourth dielectric layer 213, and portions 2131, 2133 of the fourth dielectric layer 213 extend into the spaces of the recesses 350a′, 350b′. In some embodiments, the top surfaces of the air gap structures 213A, 213B are lower than the top surface 159T of the third dielectric layer 159. The respective step is illustrated as the step S29 in the method 10 shown in FIG. 3.

It should be noted that the air gap structures (i.e., the air gap structures 213A, 213B) are formed in a semiconductor device of a pattern-dense region 1000A (i.e., a cell region), while no air gap structure exists in a semiconductor device of a pattern-sparse region (i.e., a peripheral circuit region).

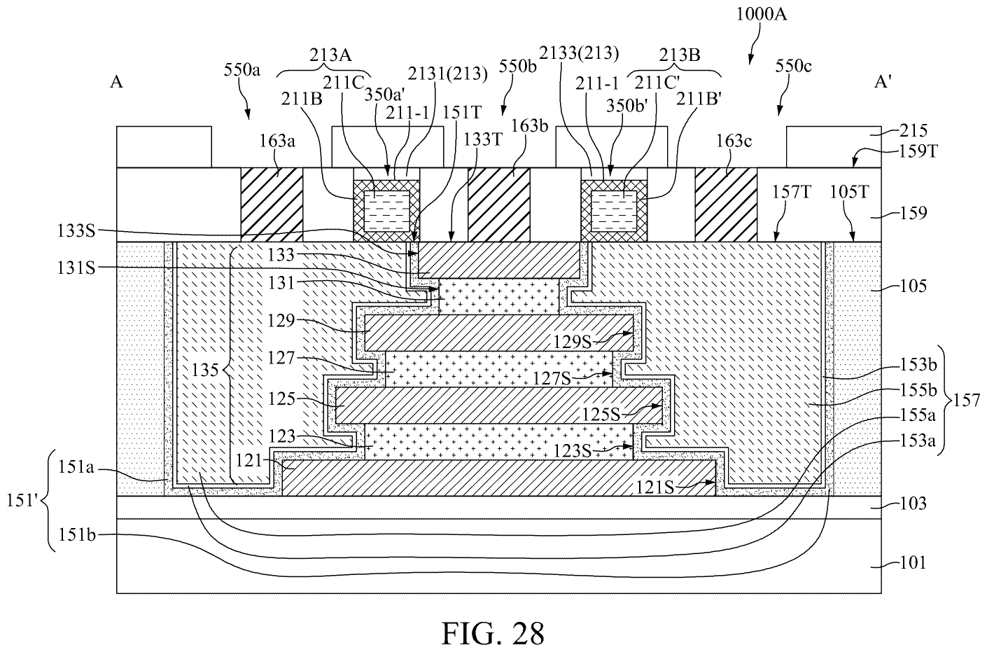

With reference to FIG. 28, in accordance with some embodiments, a patterned mask layer 215 is formed over the third dielectric layer 159, the fourth dielectric layer 213, the conductive plugs 163a, 163b, 163c, and the air gap structures 213A, 213B, wherein the patterned mask layer 215 comprises a plurality of openings 550a, 550b, 550c, and wherein the openings 550a, 550b, 550c are disposed over the conductive plugs 163a, 163b, 163c, respectively.

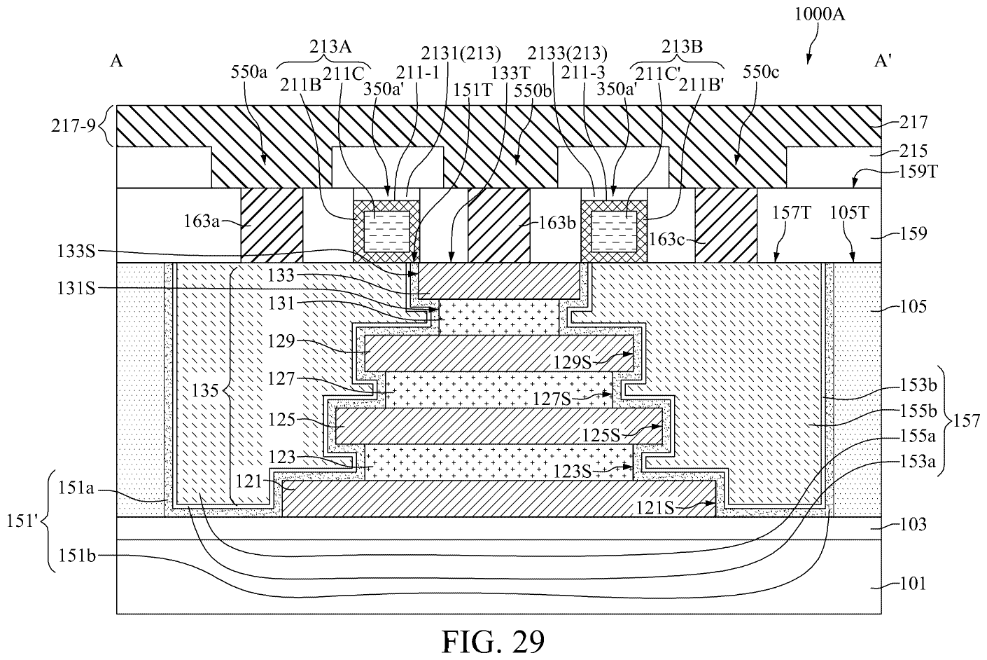

With reference to FIG. 29, in accordance with some embodiments, a conductive layer 217 may be deposited to cover the patterned mask 215 and to fill the openings 550a, 550b, 550c. Next, an etching process is performed on the conductive layer 217 using the patterned mask 215 as an etching mask. In some embodiments, the etching process may include a dry etching process, a wet etching process, or a combination thereof. After the etching process is performed, the patterned mask 215 can be removed. As a result, as shown in FIG. 1, a plurality of conductive pads 165a, 165b, 165c are formed in the openings 550a, 550b, 550c, respectively. Materials used to form the conductive pads 165a, 165b, 165c are similar to, or same as, those used to form the conductive plugs 163a, 163b, 163c, and details thereof are not repeated. The respective step is illustrated as the step S31 in the method 10 shown in FIG. 3. After the conductive pads 165a, 165b and 165c are formed, the semiconductor device 100 is obtained as shown in FIG. 1.

Embodiments of the semiconductor device 100 with the bottom electrode 135 having step-shaped sidewalls and a method of preparing the same are provided in the disclosure. The semiconductor device 100 includes the bottom electrode structure 135, the high-k dielectric structure 151′ disposed on opposite sidewalls (i.e., the sidewalls 121S, 123S, 125S, 127S, 129S, 131S and 133S) of the bottom electrode structure 135, and the top electrode structure 157 laterally surrounding the bottom electrode structure 135 and separated from the bottom electrode structure 135 by the high-k dielectric structure 151′. In some embodiments, the opposite sidewalls of the bottom electrode structure 135 are step-shaped. Therefore, since the sidewalls of the bottom electrode structure comprise step-shaped sidewalls, a capacitor formed by the bottom electrode structure 135, the high-k dielectric structure 151′, and the top electrode structure 157 can exhibit an effective area greater than those in the prior art having a same footprint area, and a capacitance per unit area can be increased. As a result, a performance of the semiconductor device 100 is improved.

One aspect of the present disclosure provides a method of fabricating a semiconductor device comprising providing a substrate; forming a first dielectric layer over the substrate and a second dielectric layer over the first dielectric layer; forming a bottom electrode structure over the first dielectric layer; forming a high-k dielectric structure on opposite sidewalls of the bottom electrode structure; forming a top electrode structure laterally surrounding the bottom electrode structure and separated from the bottom electrode structure by the high-k dielectric structure; forming a plurality of conductive plugs in a third dielectric layer over the bottom electrode structure, the high-k dielectric structure, the top electrode structure, and the second dielectric layer; forming a plurality of air gap structures in the third dielectric layer; and forming a plurality of conductive pads over the third dielectric layer. The opposite sidewalls of the bottom electrode structure are step-shaped.

Another aspect of the present disclosure provides a method of fabricating a semiconductor device comprising providing a substrate in a pattern-dense region; forming a first dielectric layer over the substrate; forming a semiconductor structure over the first dielectric layer; forming a first conductive plug, a second conductive plug and a third conductive plug over the semiconductor structure, wherein the first conductive plug, the second conductive plug and the third conductive plug are spaced apart from each other; and forming a first air gap structure and a second air gap structure over the semiconductor structure, wherein the first air gap structure is disposed between the first conductive plug and the second conductive plug and the second air gap structure is disposed between the second conductive plug and the third conductive plug.

Another aspect of the present disclosure provides a semiconductor device comprising a substrate with a first dielectric layer disposed thereon; a bottom electrode structure disposed over the first dielectric layer; a high-k dielectric structure disposed on opposite sidewalls of the bottom electrode structure, wherein the opposite sidewalls of the bottom electrode structure are step-shaped; a top electrode structure laterally surrounding the bottom electrode structure and separated from the bottom electrode structure by the high-k dielectric structure; a first conductive plug disposed over the top electrode structure, a second conductive plug disposed over the bottom electrode structure, and a third conductive plug disposed over the top electrode structure, wherein the first conductive plug, the second conductive plug and the third conductive plug are spaced apart from each other; and a first air gap structure and a second air gap structure disposed over the bottom electrode structure, the high-k dielectric structure and the top electrode structure. The bottom electrode structure comprises a first metal layer, a second metal layer disposed over the first metal layer, a third metal layer disposed over the second metal layer, a fourth metal layer disposed over the third metal layer, a fifth metal layer disposed over the fourth metal layer, a sixth metal layer disposed over the fifth metal layer, and a seventh metal layer disposed over the sixth metal layer. The first metal layer, the third metal layer, the fifth metal layer and the seventh metal layer comprise a first metal material. The second metal layer, the fourth metal layer and the sixth metal layer comprise a second metal material different from the first metal material. The first air gap structure is disposed between the first conductive plug and the second conductive plug. The second air gap structure is disposed between the second conductive plug and the third conductive plug.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method of fabricating a semiconductor device, comprising:
providing a substrate;
forming a first dielectric layer over the substrate and a second dielectric layer over the first dielectric layer;
forming a bottom electrode structure over the first dielectric layer;
forming a high-k dielectric structure on opposite sidewalls of the bottom electrode structure, wherein the opposite sidewalls of the bottom electrode structure are step-shaped;
forming a top electrode structure laterally surrounding the bottom electrode structure and separated from the bottom electrode structure by the high-k dielectric structure;
forming a plurality of conductive plugs in a third dielectric layer over the bottom electrode structure, the high-k dielectric structure, the top electrode structure, and the second dielectric layer;
forming a plurality of air gap structures in the third dielectric layer; and
forming a plurality of conductive pads over the third dielectric layer.

2. The method of claim 1, wherein the formation of the bottom electrode structure comprises:
performing an etching process to form an opening in the second dielectric layer;
sequentially forming a first metal layer, a second metal layer, a third metal layer, a fourth metal layer, a fifth metal layer, a sixth metal layer, and a seventh metal layer in the opening; and
performing an etching process on each of the first metal layer, the second metal layer, the third metal layer, the fourth metal layer, the fifth metal layer, the sixth metal layer and the seventh metal layer.

3. The method of claim 1, wherein the formation of the high-k dielectric structure comprises:
conformally depositing a high-k dielectric layer over the bottom electrode structure, the first dielectric layer and the second dielectric layer; and
performing a planarization process on the high-k dielectric layer.

4. The method of claim 1, wherein the formation of the top electrode structure comprises:
conformally depositing a seed layer over the high-k dielectric layer;
depositing a conductive layer over the high-k dielectric layer; and
performing a planarization process on the seed layer and the conductive layer.

5. The method of claim 1, wherein the formation of the plurality of conductive plugs in the third dielectric layer comprises:
forming the third dielectric layer over the bottom electrode structure, the high-k dielectric structure and the top electrode structure;
forming a plurality of openings in the third dielectric layer;
depositing a conductive material in the openings and over the third dielectric layer; and
performing a planarization process on the conductive material).

6. The method of claim 1, wherein the formation of the plurality of air gap structures comprises:
forming a plurality of openings in the third dielectric layer;
depositing an energy-removable layer to cover the conductive plugs and the third dielectric layer and to fill the openings;
sequentially performing a planarization process and an etching process to respectively remove a portion of the energy-removable layer over the third dielectric layer and portions of the energy-removable layer in the openings, and forming energy-removable blocks in the openings;
depositing a fourth dielectric layer to cover the conductive plugs, the energy-removable blocks, and the third dielectric layer;
performing a thermal treatment process to transform the energy-removable blocks into a plurality of air gap structures; and
performing a planarization process to remove a portion of the fourth dielectric layer over the third dielectric layer.

7. The method of claim 1, wherein the formation of the plurality of conductive pads comprises:
forming a mask layer over the third dielectric layer, wherein the mask layer comprises a plurality of openings;
depositing a conductive layer covering the mask layer and filling the openings;
removing a portion of the conductive layer over the mask; and
removing the mask.

8. A method of fabricating a semiconductor device, comprising:
providing a substrate in a pattern-dense region;
forming a first dielectric layer over the substrate;
forming a semiconductor structure over the first dielectric layer;
forming a first conductive plug, a second conductive plug and a third conductive plug over the semiconductor structure, wherein the first conductive plug, the second conductive plug and the third conductive plug are spaced apart from each other; and
forming a first air gap structure and a second air gap structure over the semiconductor structure, wherein the first air gap structure is disposed between the first conductive plug and the second conductive plug and the second air gap structure is disposed between the second conductive plug and the third conductive plug.

9. The method of claim 8, wherein the formation of the semiconductor structure comprises:
forming a bottom electrode structure over the first dielectric layer;
forming a high-k dielectric structure on opposite sidewalls of the bottom electrode structure, wherein the opposite sidewalls of the bottom electrode structure are step-shaped; and
forming a top electrode structure laterally surrounding the bottom electrode structure and separated from the bottom electrode structure by the high-k dielectric structure.

10. The method of claim 9, wherein the formation of the bottom electrode structure comprises:
performing an etching process to form an opening in a second dielectric layer over the first dielectric layer;
sequentially forming a first metal layer, a second metal layer, a third metal layer, a fourth metal layer, a fifth metal layer, a sixth metal layer, and a seventh metal layer in the opening; and
performing an etching process on each of the first metal layer, the second metal layer, the third metal layer, the fourth metal layer, the fifth metal layer, the sixth metal layer and the seventh metal layer.

11. The method of claim 10, wherein the formation of the high-k dielectric structure comprises:
conformally depositing a high-k dielectric layer over the bottom electrode structure, the first dielectric layer and the second dielectric layer; and
performing a planarization process on the high-k dielectric layer.

12. The method of claim 11, wherein the formation of the top electrode structure comprises:
conformally depositing a seed layer over the high-k dielectric layer;
depositing a conductive layer over the high-k dielectric layer; and
performing a planarization process on the seed layer and the conductive layer.

13. The method of claim 12, wherein the formation of the first conductive plug, the second conductive plug and the third conductive plug comprises:
forming a third dielectric layer over the semiconductor structure and the second dielectric layer;
forming a first opening, a second opening and a third opening in the third dielectric layer;
depositing a conductive material covering the third dielectric layer and filling the first opening, the second opening and the third opening; and
performing a planarization process on the conductive material).

14. The method of claim 13, wherein the formation of the first air gap structure and the second air gap structure comprises:
forming a fourth opening and a fifth opening in the third dielectric layer, wherein the fourth opening is disposed between the first conductive plug and the second conductive plug, and the fifth opening is disposed between the second conductive plug and the third conductive plug;
forming an energy-removable layer covering the first metal plug, the second metal plug, the third metal plug and the third dielectric layer, and filling the fourth opening and the fifth opening;
performing an etching process to remove a portion of the energy-removable layer from the third dielectric layer, while leaving intact a first energy-removable block between the first metal plug and the second metal plug and a second energy-removable block between the second metal plug and the third metal plug in the pattern-dense region;
forming a fourth dielectric layer covering the first energy-removable block, the second energy-removable block, the first metal plug, the second metal plug, the third metal plug, and the third dielectric layer;
performing a thermal treatment process to transform the first energy-removable block into a first air gap structure and to transform the second energy-removable block into a second air gap structure, wherein the first air gap structure includes a first air gap enclosed by a first liner layer and the second air gap structure includes a second air gap enclosed by a second liner layer; and
performing a planarization process to remove a portion of third dielectric layer over the third dielectric layer;
wherein a first portion of the fourth dielectric layer is disposed between the first metal plug and the second metal plug and a second portion of the fourth dielectric layer is disposed between the second metal plug and the third metal plug, such that the first portion of the fourth dielectric layer and the semiconductor structure are separated by the first air gap and the second portion of the fourth dielectric layer and the semiconductor structure are separated by the second air gap.
